(19) United States
(12) Patent Application Publication
(10) Pub. No.: US 2012/0295376 A1
(43) Pub. Date: Nov. 22, 2012

(54) METHOD FOR MANUFACTURING A LED ARRAY DEVICE, AND LED ARRAY DEVICE MANUFACTURED THEREBY

(75) Inventors: Keon Jae LEE, Daejeon (KR); So Young PARK, Daejeon (KR); Seung Hyun LEE, Asan-si (KR); Kwi Il PARK, Gumi-si (KR); Min KOO, Bucheon-si (KR)

(73) Assignee: KOREA ADVANCED INSTITUTE OF SCIENCE AND TECHNOLOGY, Daejeon (KR)

(21) Appl. No.: 13/473,300

(22) Filed: May 16, 2012

(30) Foreign Application Priority Data
May 16, 2011 (KR) 10-2011-0045646
Jul. 12, 2011 (KR) 10-2011-0068830
Sep. 5, 2011 (KR) 10-2011-0089822
Jan. 18, 2012 (KR) 10-2012-0005866

(51) Int. Cl. H01L 33/30; H01L 33/08

(52) U.S. Cl. 438/28; 438/26; 257/E33.056

(57) ABSTRACT

Disclosed are a method for fabricating a GaN LED array device for optogenetics and a GaN LED array device fabricated thereby.

### TECHNICAL FIELD

The present disclosure relates to a method for fabricating an LED array device and an LED array device fabricated thereby. More particularly, the disclosure relates to a method for fabricating an LED array device which has light weight, is implantable and can be used in a small space through size control via a simple economical process, and an LED array device fabricated thereby.

### BACKGROUND ART

Light-emitting diode (LED) devices are used for various purposes. One of the applications of the device is a medical application using light of specific frequency. An example is the field of optogenetics, which combines optics with genetics. The concept was developed and advanced by Professor Deisseroth's group at Stanford University. The optogenetics is a cutting-edge technology of controlling neurons. After inserting cell membrane protein genes sensitive to light such as channelrhodopsin-2 (ChR2; responds to blue light emitted from GaN) into the neurons of an experimental animal using a viral vector, the neurons can be activated or deactivated by stimulating with light of different wavelengths. The photostimulation by the optogenetic technique allows more elaborate control of neurons with high temporal and spatial resolution as compared to electrical stimulation using the electrophysiological technique. Until recently, in the experiments using the optogenetic technique, an optical fiber connected to outside was inserted to stimulate a deep region of the brain. However, this method may result in brain damage and it is difficult to provide a stimulus of a desired pattern to the brain since the site of stimulation is restricted to a specific area. That is to say, the problem of the existing techniques arises because the light source is made of a hard material whereas the brain is round and has many crevices. Accordingly, when a bendable and flexible light source is used, it will be possible to provide stimulation without damaging the brain and to provide a stimulus of a specific pattern to the brain. If the light source is driven by a flexible battery implanted in the body or if the battery can be recharged with the energy generated in the body by a nanogenerator, freer activities will be ensured for experimental animals or patients in the long term, without connection to outside or additional surgery.

Laser or LED is used as light source for treating a variety of skin diseases or wounds. The laser therapy is employed for removal of freckles, hair, scar, etc. to remove or destroy the skin cells in short time, whereas the LED therapy is being developed mainly for the treatment of chronic skin diseases, skin aging, wound, freckles, etc. that require a long period of time.

However, since these skin therapies involve radiation of light from a long distance using expensive light irradiation devices, the light may be irradiated to unwanted part of the skin and the light intensity decreases due to the long distance from the light source to the skin.

### DISCLOSURE

### Technical Problem

The present disclosure is directed to providing a flexible, inorganic-based LED device for photostimulation.

### Technical Solution

In an aspect, the present disclosure provides a method for fabricating a flexible LED device, including: separating an LED device fabricated on a sacrificial substrate from the sacrificial substrate; and transferring the separated LED device to a plastic substrate.

### Advantageous Effects

The flexible LED device according to the present disclosure may be separated from a substrate by a dry method using, for example, a laser beam and transferred to another substrate. Therefore, it can easily stimulate the uneven surface of the round skull or the cerebral cortex (associated with recognition, thinking, language, memory etc.; in particular, Parkinson's disease is associated with damage to the neurons on the surface of the cerebral cortex) just below the skull and can be implanted in the deep narrow crevice between the left and right cerebral hemispheres. Since a plurality of LEDs that can be turned on/off independently are arranged as an array, neurons of several areas can be stimulated with light and thus it becomes easier to understand the neural circuitry.

In addition, since the flexible LED device according to the present disclosure is biocompatible, the light source can be attached directly to the skin to irradiate light. Accordingly, the decrease of light intensity caused by the distance from the light source can be prevented and high-intensity light can be effectively transferred to the skin.

### DESCRIPTION OF DRAWINGS

FIGS. 1-24 schematically illustrate a method for fabricating a flexible GaN LED array device according to an exemplary embodiment of the present disclosure.

FIGS. 25-29 illustrate a method for photostimulation using a flexible GaN LED device for optogenetics according to an exemplary embodiment of the present disclosure.

FIGS. 30-59 illustrate a method for fabricating a flexible GaN LED device according to an exemplary embodiment of the present disclosure.

FIG. 60 schematically illustrates a method for providing a patterned stimulation using a flexible LED array (800a, 800b) according to an exemplary embodiment of the present disclosure and reading the response using an MEA (800c).

FIG. 61 illustrates an exemplary use of an optical device for optogenetics according to an exemplary embodiment of the present disclosure.

### MODE FOR INVENTION

Hereinafter, the embodiments of the present disclosure will be described in detail with reference to specific examples and accompanying drawings. The following examples are provided for illustrative purposes only and not intended to limit the scope of the present disclosure. Those skilled in the art will appreciate that the present disclosure can be embodied in other forms without being limited to the examples. In the attached drawings, the specific design features of the drawings, including, for example, width, length, thickness, etc. may be somewhat exaggerated for convenience of description. Throughout the specification, the same reference numerals refer to the same elements.

And, all the attached drawings are plan views or partial cross-sectional views along the line A-A′.

As used herein, the term “ plastic substrate” is understood to include all substrates having flexible properties. More specifically, it refers to a flexible polymer substrate.

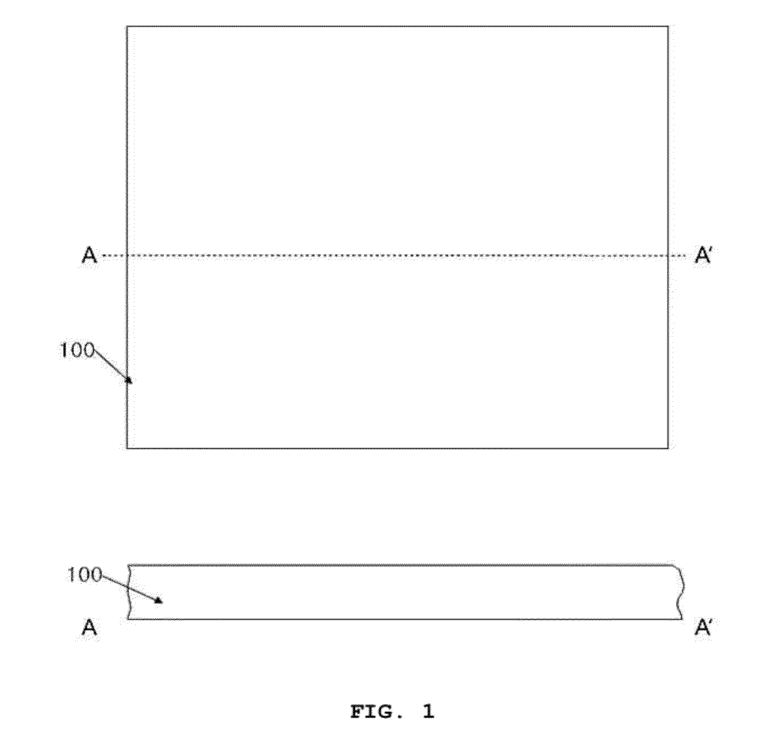

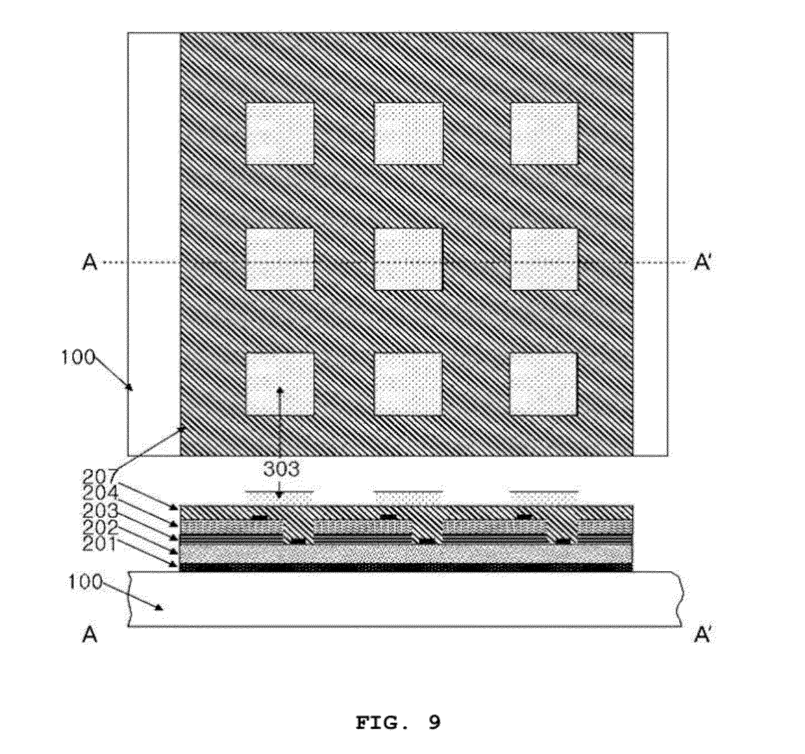

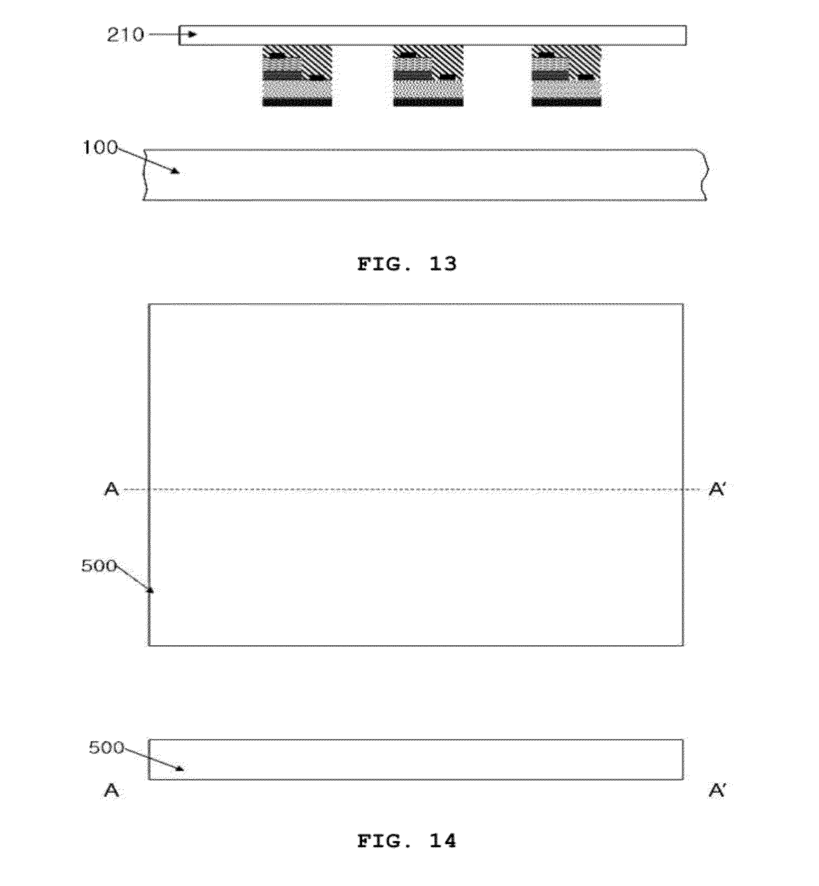

FIGS. 1-24 schematically illustrate a method for fabricating a flexible GaN LED array device according to an exemplary embodiment of the present disclosure. In an exemplary embodiment of the present disclosure, the LED device may be a GaN or GaAs LED device and may be used for medical uses such as optogenetics, skin therapy, or the like.

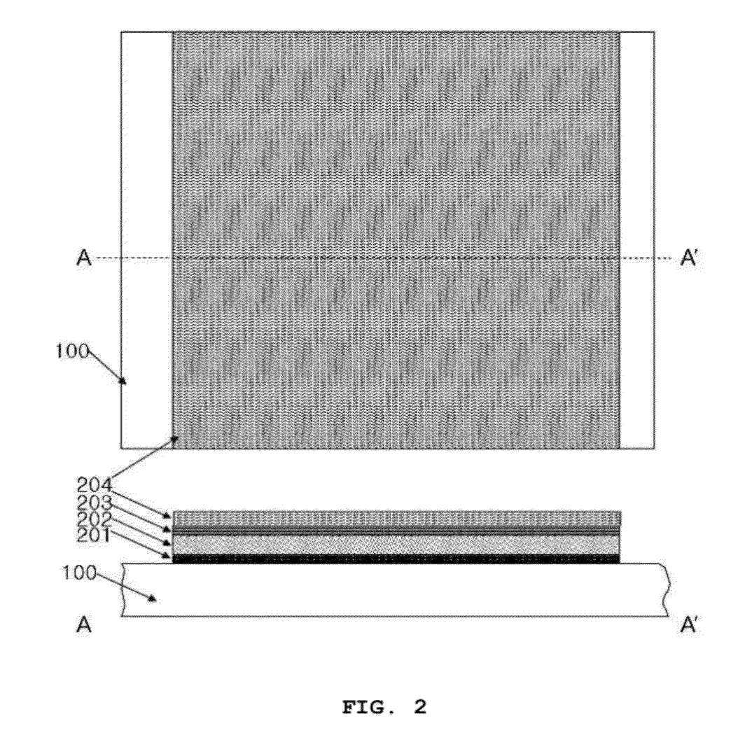

FIG. 1 shows a sapphire substrate (100) as a sacrificial substrate. Referring to FIG. 2, a buffer layer (201), an n-GaN layer (202), a multi-quantum well (MQW) layer (203) as an active layer and a p-GaN layer (204) are formed sequentially on the substrate (100). The n-GaN layer and the p-GaN layer refer to an n-type impurity- and a-type impurity-doped GaN layer, respectively.

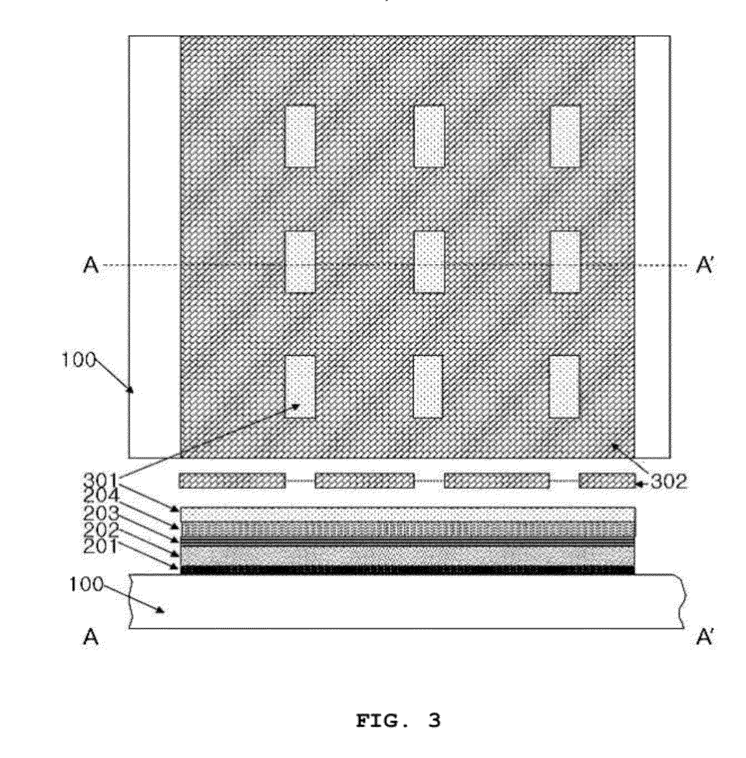

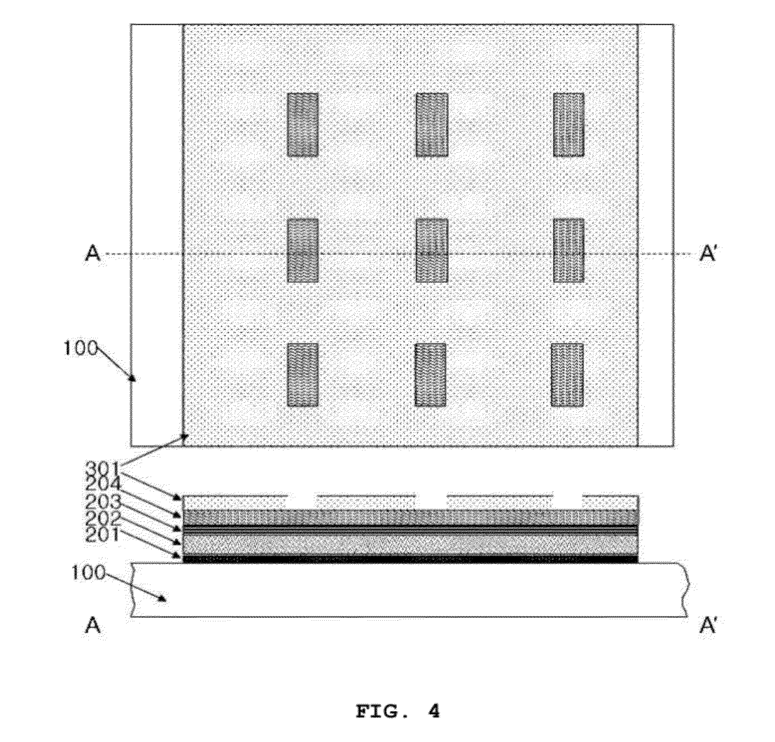

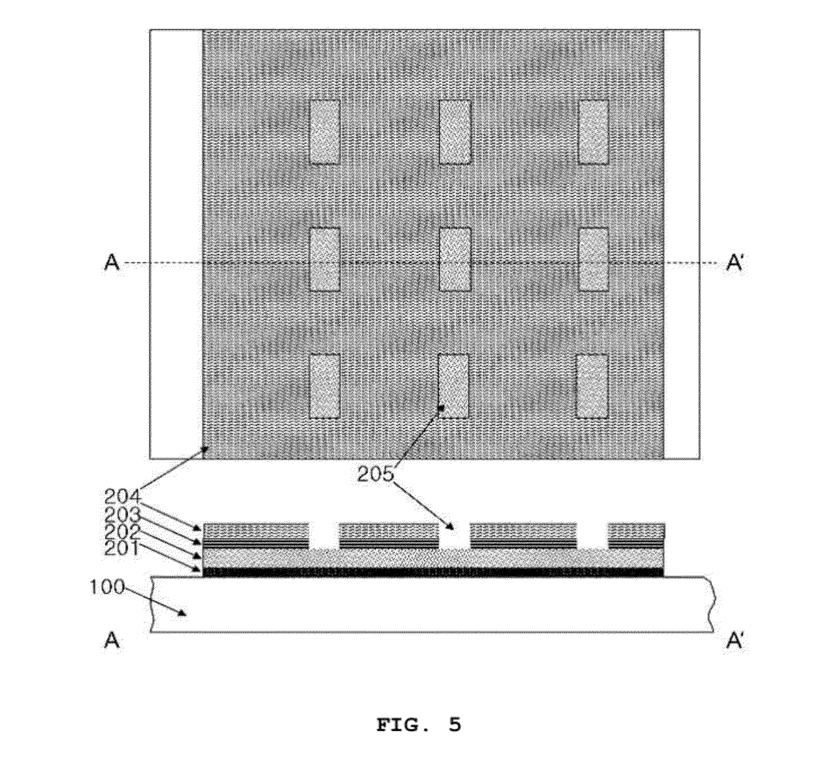

Referring to FIG. 3, a photoresist layer (301) is coated on the p-GaN layer (204), and a photoresist process is performed using a patterned first mask (302) to sequentially etch the p-GaN layer and the multi-quantum well layer, thereby exposing the n-GaN layer (202) to outside (see FIGS. 4 and 5). The exposed region of the n-GaN layer (205) is spaced apart from each other and may have a rectangular structure with predetermined width and length. However, the scope of the present disclosure is not limited thereto.

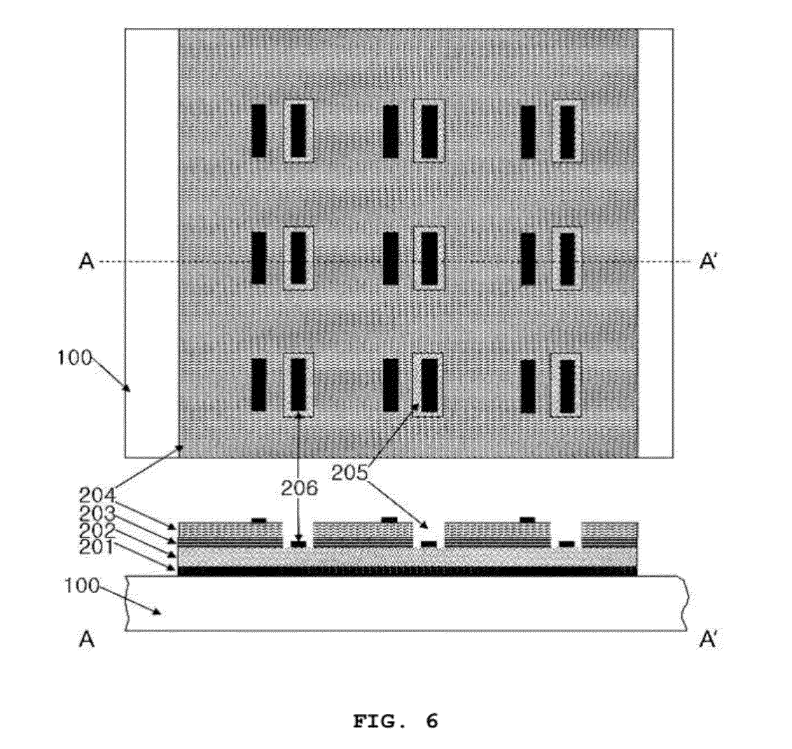

Referring to FIG. 6, a first and a second contact metals (206) are formed on the exposed region of the n-GaN layer (205) and on a neighboring p-GaN layer (204). In an exemplary embodiment of the present disclosure, the contact metal (206) is Au/Cr alloy, and an ohmic contact is formed with the layer therebelow by heat-treating at 600° C. for 1 minute.

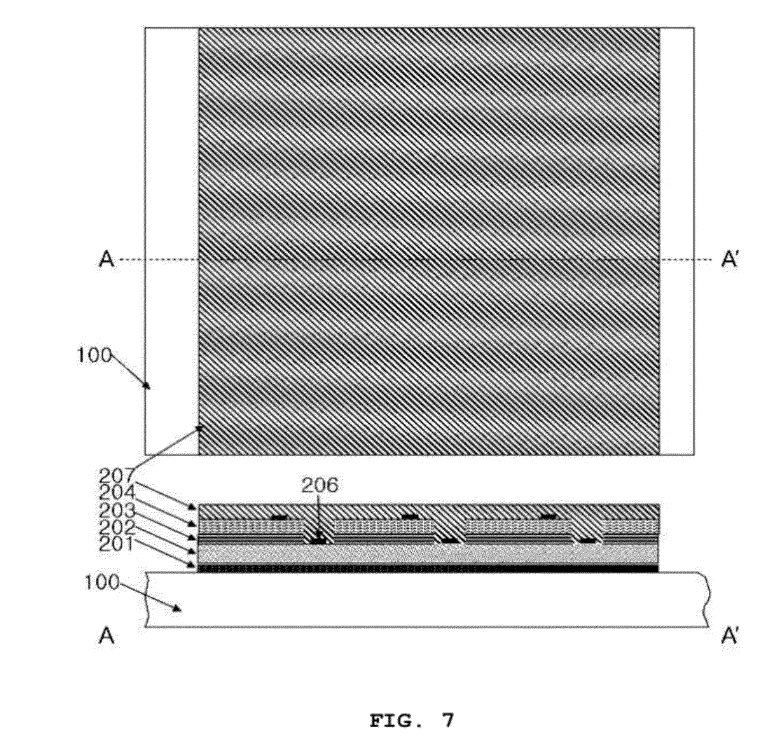

Referring to FIG. 7, a first metal layer (207) is formed on the whole device layer and, as a result, the exposed region of the n-GaN layer and the p-GaN layer are covered by the support metal layer, that is the first metal layer (207). In the present disclosure, the support metal layer (207) provides a uniform contact area for transfer of a GaN device to a transfer substrate.

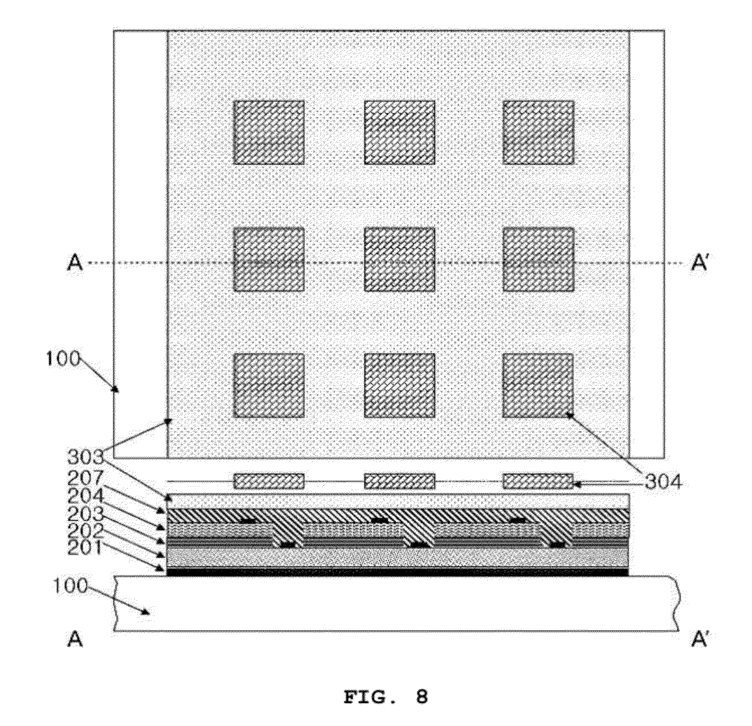

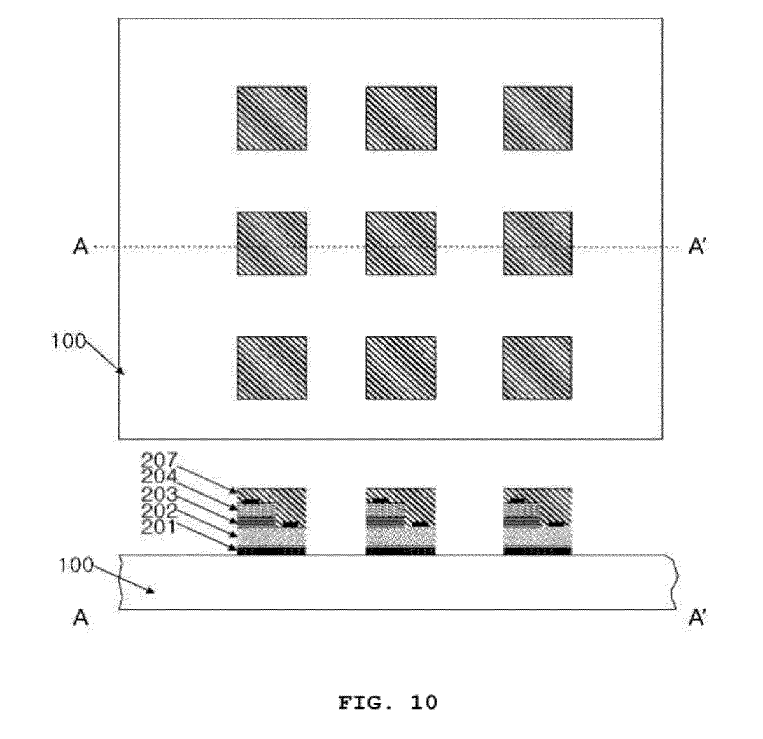

Referring to FIGS. 8-10, after disposing a second mask (304) on the region of a unit device comprising the first and second contact metals, etching is performed via a photoresist process. As a result, all of the device layer is removed except for the device region on which the second mask (304) is formed. Here, the device region refers to the region of the n-GaN layer (205) and the neighboring region of the p-GaN layer having the second contact metal thereon. As seen from FIG. 10, a GaN LED array wherein a plurality of the unit LED devices are formed on the hard sacrificial substrate (100) being spaced apart from each other is formed. After transfer, a contact line is formed on the GaN LED device so that the GaN LED devices can be turned on/off independently.

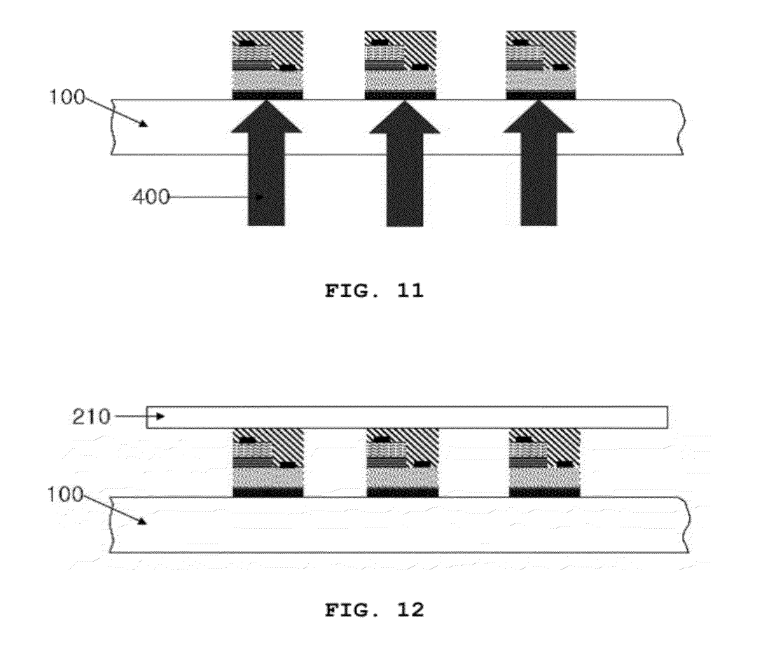

Referring to FIGS. 11-13, a laser beam (400) is irradiated on the rear surface of the sacrificial substrate (100) at locations corresponding to the device region for a lift-off process. Subsequently, a transfer substrate (210) such as PDMS is contacted with the unit device and then detached, such that the device is separated from the sacrificial substrate (100).

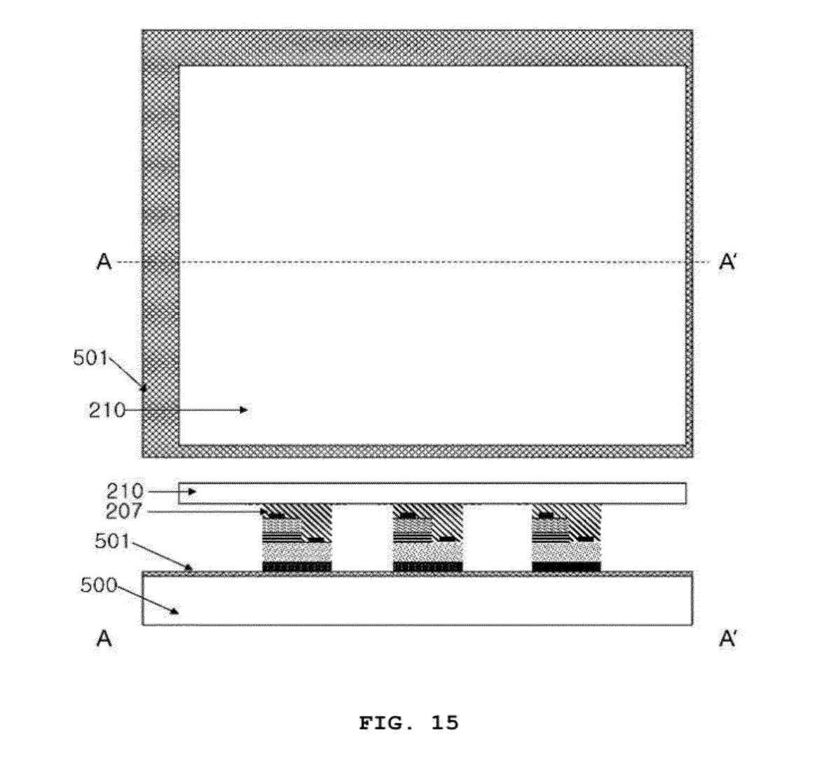

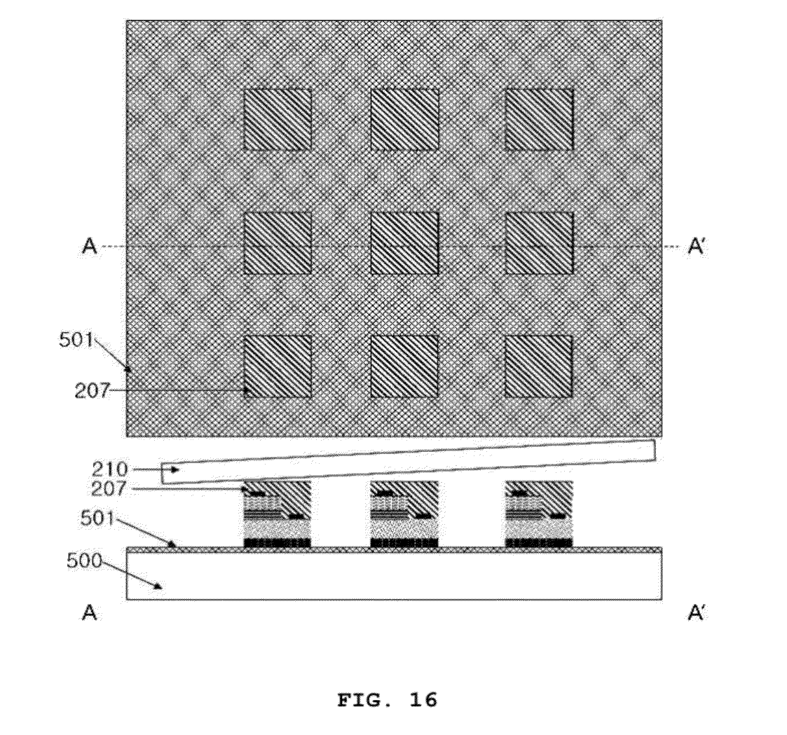

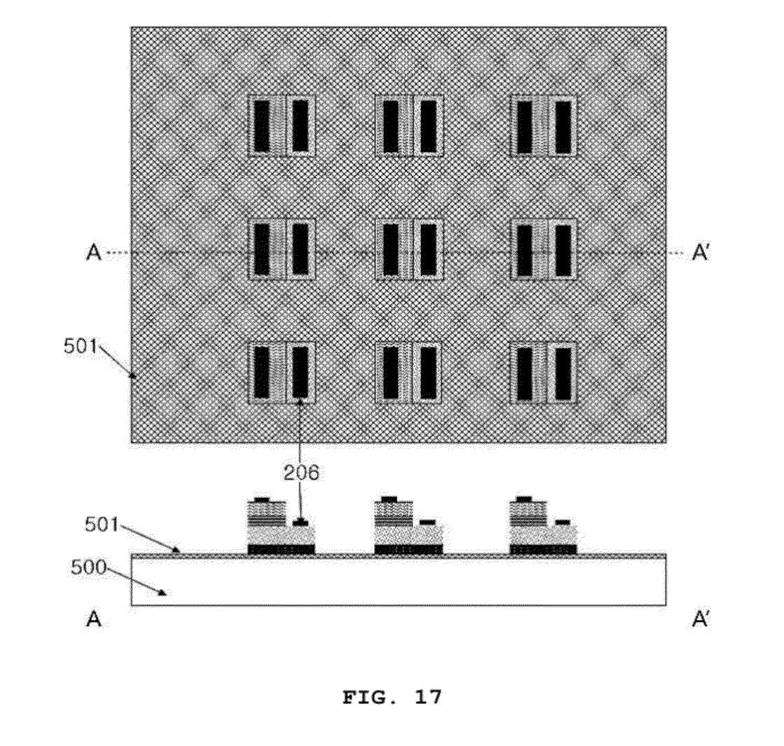

FIG. 14 shows a flexible plastic substrate (500). Referring to FIGS. 15 and 16, an adhesive layer (501) is coated on the plastic substrate (500) and then the device separated from the sacrificial substrate (100) is contacted with the adhesive layer (501) so as to transfer the device.

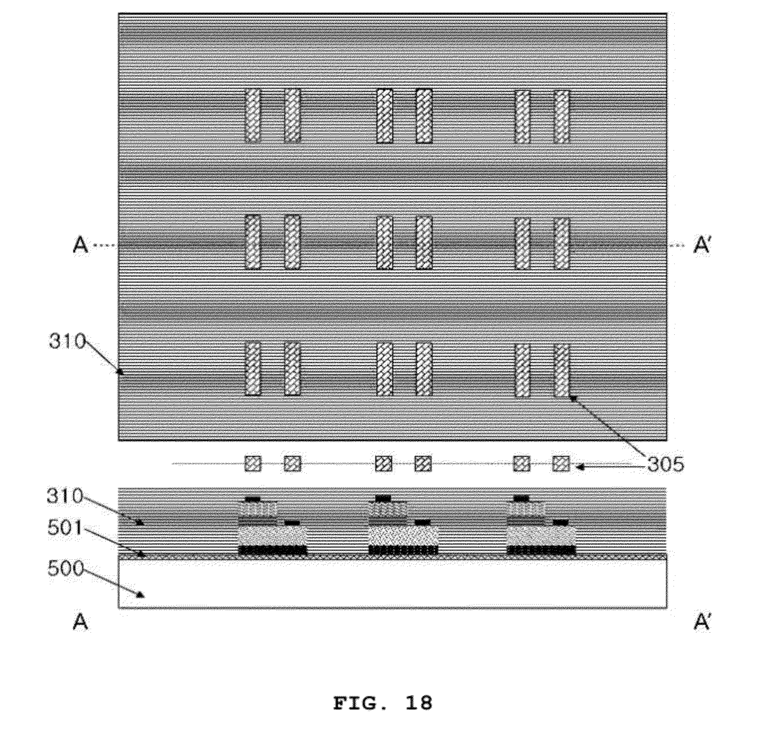

Referring to FIG. 17, the metal support layer is removed and, as a result, the n-GaN layer and the p-GaN layer are exposed. At the same time, the contact metal (206) on the n-GaN layer is also exposed. The removal may be performed by a wet method using an etchant. However, the scope of the present disclosure is not limited thereto.

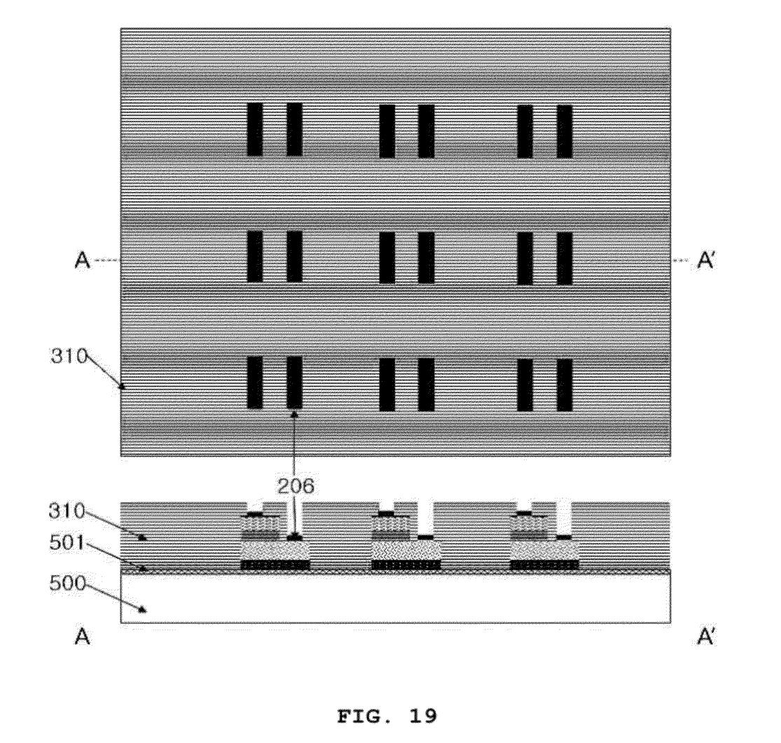

Referring to FIG. 18, a first passivation layer (310) for electrical passivation is formed. In the present disclosure, the first passivation layer (310) is a transparent resin layer. SU8, PI, PU, or the like may be used to form the passivation layer (310). Then, a third mask (305) is used to form a contact line with the contact metal on the n-GaN layer and the p-GaN layer and, as seen from FIG. 19, the contact metal (206) on the n-GaN layer and the p-GaN layer is etched and exposed to outside.

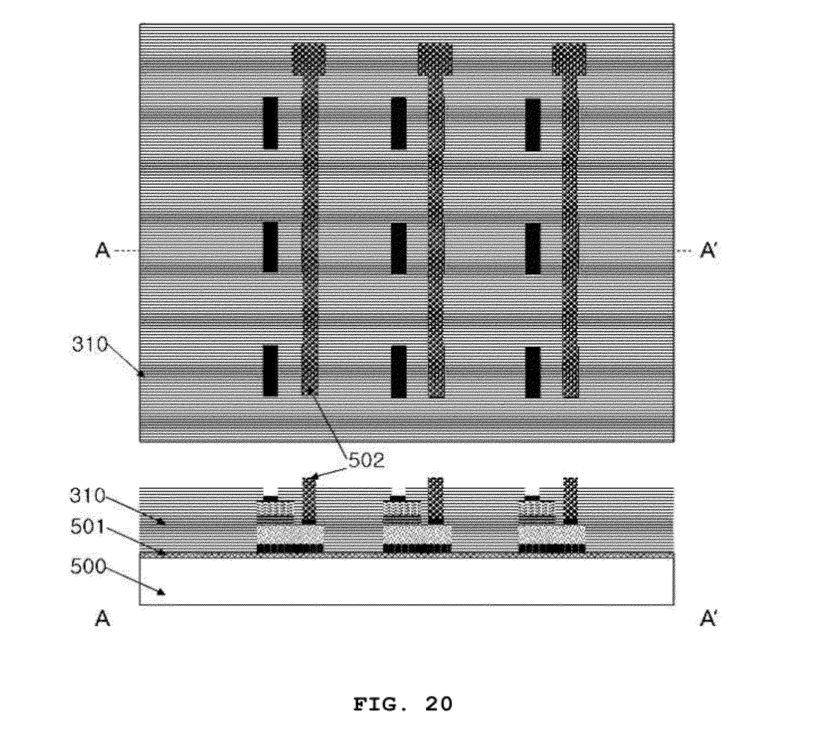

Referring to FIG. 19, patterning is performed after a first metal line (502) is formed on the contact metal on the n-GaN layer. The first metal line is formed to fill all the region etched in FIG. 19. Then, patterning is performed such that the plurality of unit devices are connected with one line. Referring to FIG. 20, three unit devices are electrically connected by one first metal line (502), and a pad which is wider than the line is formed at the end of the first metal line (502).

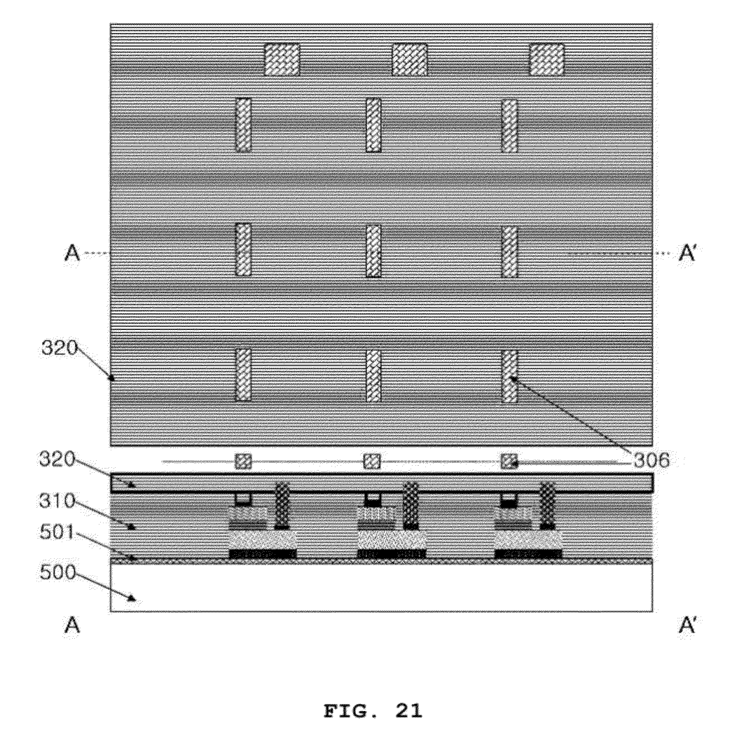

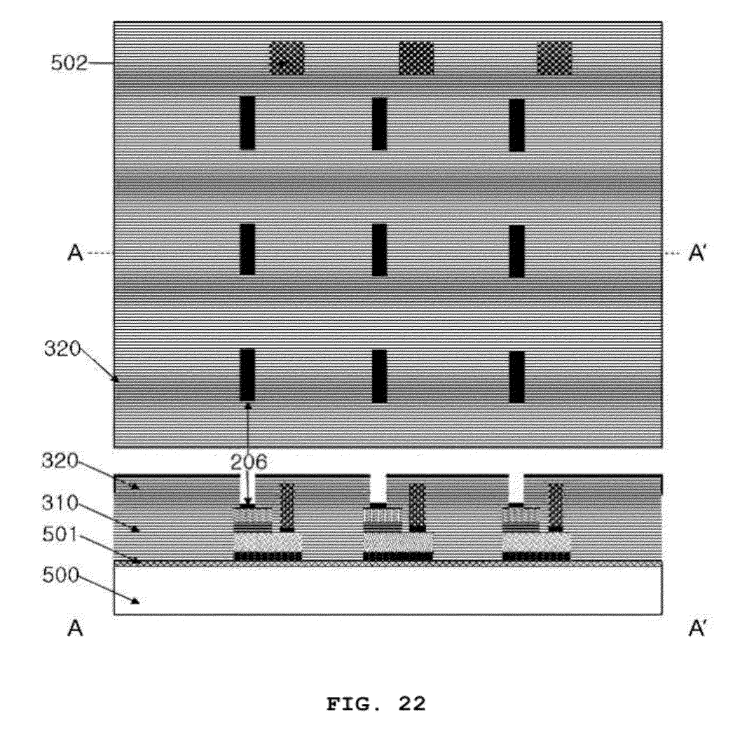

Referring to FIGS. 21 and 22, a second passivation layer (320) is formed on the device, and a photoresist process is performed using a mask (306). As a result, the contact metal (206) on the p-GaN layer is exposed as shown in FIG. 22, and the pad at the end of the first metal line (502) connected to the contact metal on the n-GaN layer is also exposed as shown in FIG. 20.

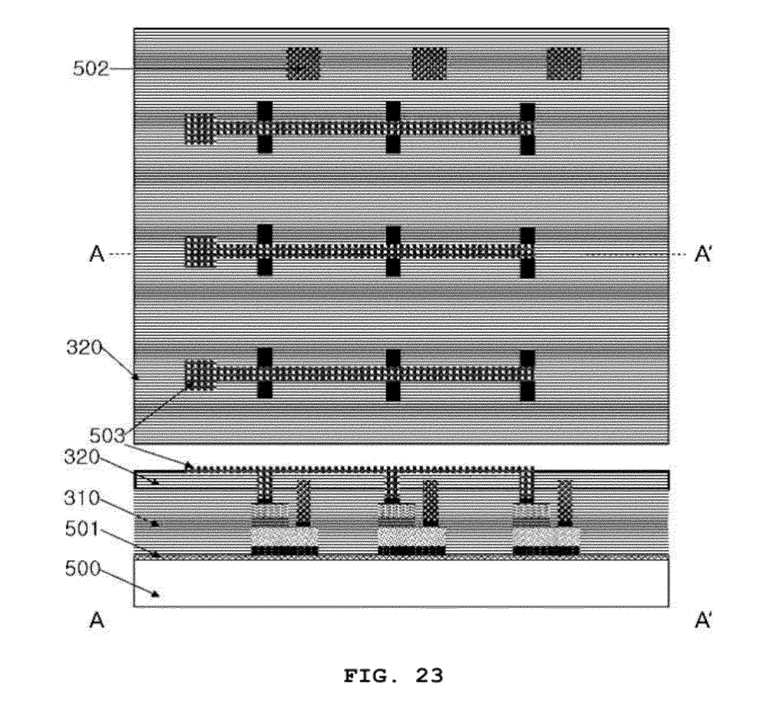

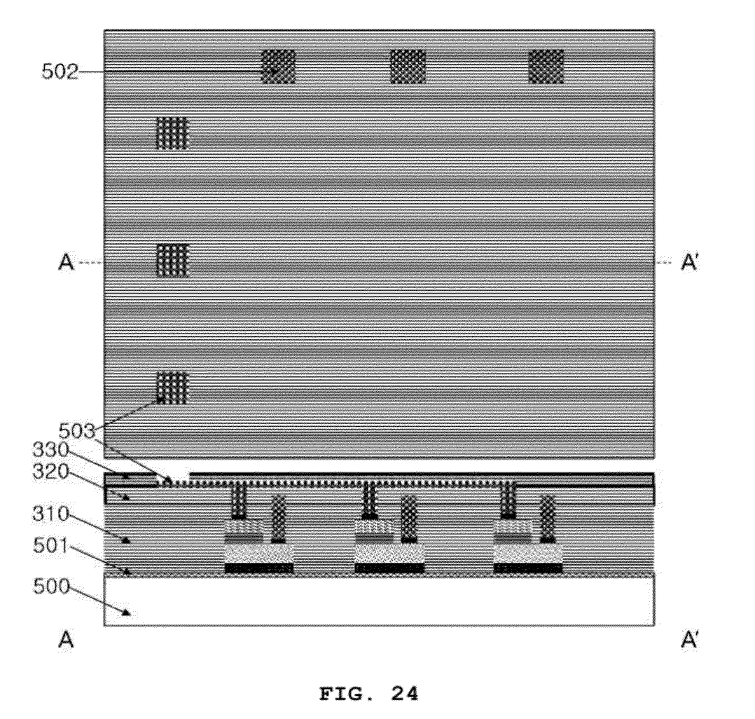

Referring to FIG. 23, a second metal line having a first contact line (502) and a second contact line (503) is formed. As a result, the first contact line (502) connected to the contact metal on the n-GaN layer and the second contact line (503) connected to the contact metal on the p-GaN layer are formed. The first contact line (502) and the second contact line (503) cross each other perpendicularly at different heights. That is to say, the first contact line (502) and the second contact line (503) electrically connect the plurality of unit devices horizontally and vertically. Also, a pad which is wider than the line is formed at the end of the second contact line (503).

Referring to FIG. 24, after a third passivation layer (330) is formed on the device, the third passivation layer (330) is patterned such that the pad at the end of the second contact line (503) is exposed for electrically connection.

As a result, a flexible GaN LED device for optogenetics wherein only the pad of the first contact line and the pad of the second contact line are exposed by the third passivation layer (330) is fabricated.

The flexible GaN LED device according to the present disclosure can easily stimulate the uneven surface of the round skull or the cerebral cortex (associated with recognition, thinking, language, memory etc.; in particular, Parkinson's disease is associated with damage to the neurons on the surface of the cerebral cortex) just below the skull and can be implanted in the deep narrow crevice between the left and right cerebral hemispheres.

Further, since a plurality of LEDs that can be turned on/off independently are arranged as an array, neurons of several areas can be stimulated with light and thus it becomes easier to understand the neural circuitry.

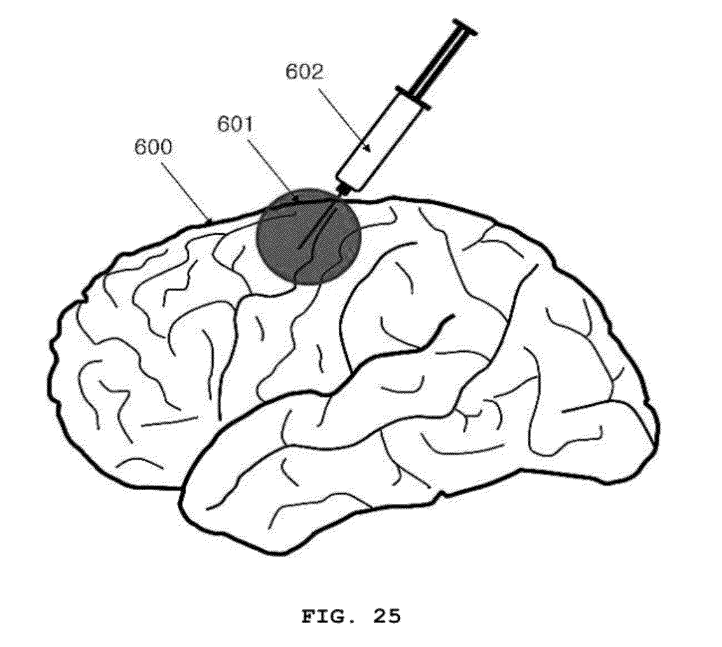

FIGS. 25-29 illustrate a method for photostimulation using a flexible GaN LED device for optogenetics according to an exemplary embodiment of the present disclosure.

Referring to FIG. 25, opsin [e.g., channelrhodopsin-2 (ChR2)] is injected into the neurons of the cerebral cortex.

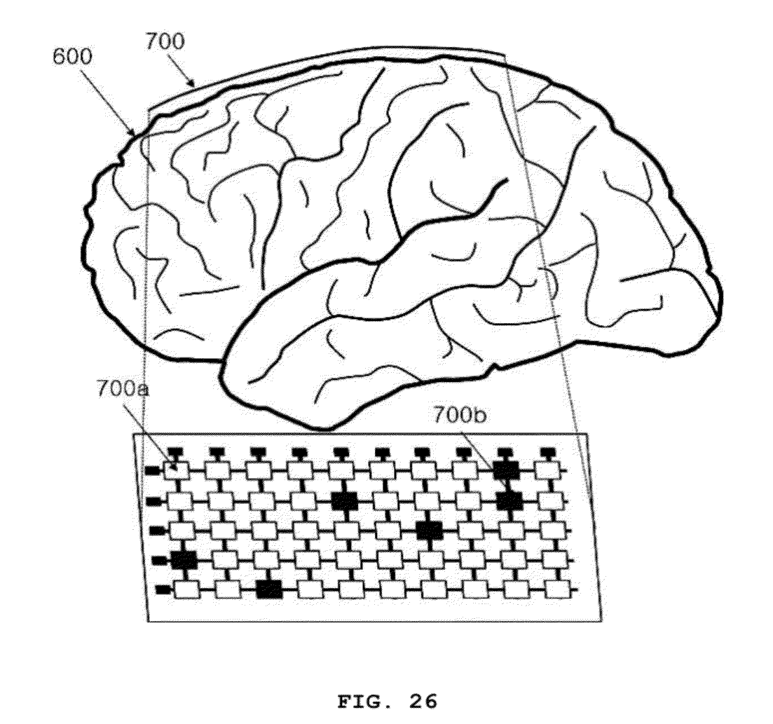

Referring to FIG. 26, light emitted from a GaN LED array device (700) according to the present disclosure stimulates the brain where the opsin (ChR2) is injected. Some unit GaN LED devices (700a) of the GaN LED array device (700) emit light while others (700b) do not. That is to say, the GaN LED device for optogenetics fabricated according to the present disclosure emits blue light with wavelength 470 nm or shorter and thus activates the proteins that respond thereto. ChR2 is stimulated by the blue light emitted from the GaN LED device.

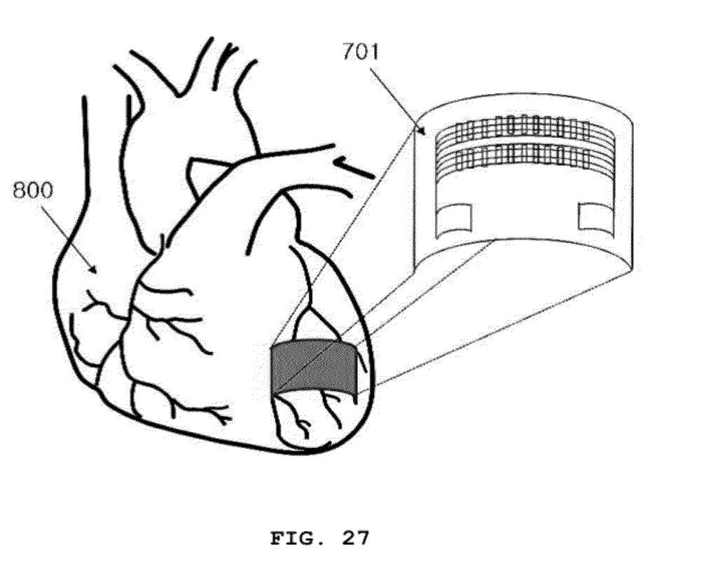

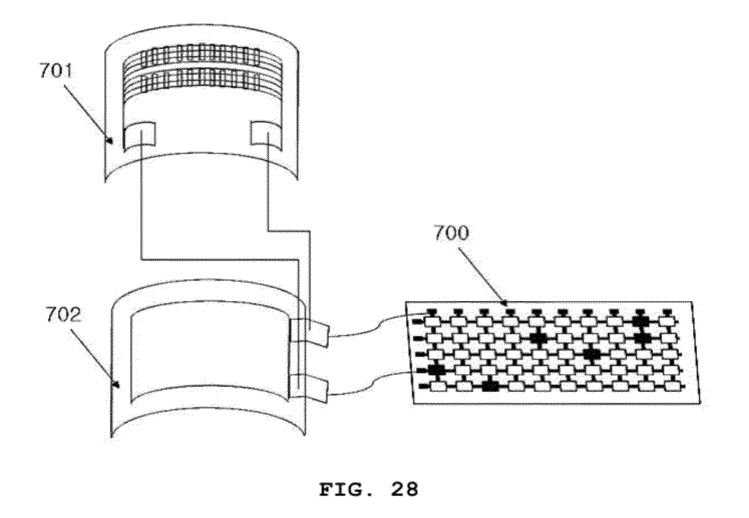

FIGS. 27 and 28 show an example wherein the GaN LED device for optogenetics according to the present disclosure is used together with a nanogenerator.

FIGS. 27 and 28 show a nanogenerator (701) which is attached to the heart and is capable of generating power from heartbeats. The power generated by the nanogenerator (701) is charged in a flexible secondary battery (702), which in turn supplies electricity to the GaN LED array device (700) according to the present disclosure. Accordingly, freer activities can be ensured for experimental animals or patients, without requiring connection to outside or additional surgery.

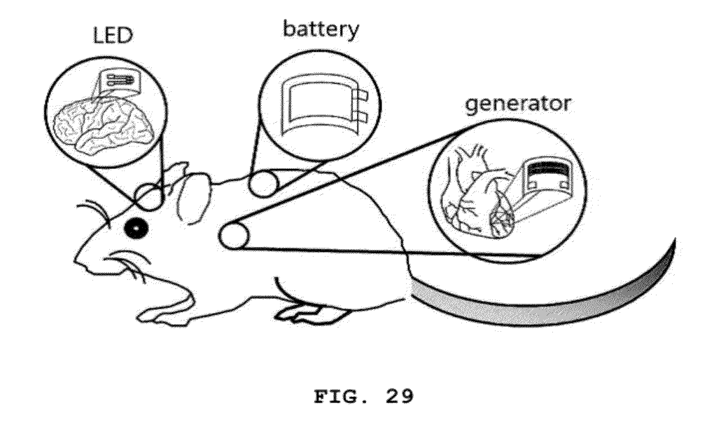

FIG. 29 shows various exemplary uses of the GaN LED array device according to the present disclosure.

Referring to FIG. 29, the brain of a living mouse can be selectively stimulated using a flexible LED device and the change in motion of the mouse can be monitored. Alternatively, after fixing the mouse on a stereotaxic frame, various parts of the brain may be stimulated and the behavioral change of the mouse can be monitored. This enables site-specific and stimulation pattern-specific functional studies.

The GaN LED array device according to the present disclosure is very useful for optogenetics in that it has light weight, is implantable and can be used in a small space through size control. For example, the spinal neurons branching through the bones of the spine may be easily damaged in case of disc herniation, external injury, spinal curvature, or the like. The damage to the spinal neurons is associated with various physical symptoms (problems with digestive organs, heart, blood vessels, bladder, sweat glands, etc.). However, since the spine is not straight but curved, it is impossible to use a hard LED. In contrast, the flexible LED device according to the present disclosure may be implanted for use under such environments. In particular, the optogenetic system according to the present disclosure that can be self-powered in vivo is very useful for the patients who cannot move freely.

Further, the present disclosure provides an optical LED device for skin therapy which is capable of irradiating light to only desired locations as being attached to the curved skin surface. For this, the present disclosure provides an LED device embodied on a flexible substrate as the optical device for skin therapy. In particular, when GaAs is used as a light-emitting layer, the red light emitted from the layer may promote the generation of cellular components such as collagen, elastin, etc. which sustain skin elasticity. And, when GaN is used as the light-emitting layer, the blue light emitted from the layer may prevent the growth of bacteria causing skin troubles, thereby maintaining healthy skin and treating acne, atopy, etc. Therefore, the optical device for skin therapy according to the present disclosure may be used to treat various skin diseases using different lights emitted from different light-emitting layers.

Further, the biocompatible, flexible LED device according to the present disclosure can directly irradiate light to tissues for photodynamic therapy. Since the flexible optical device according to the present disclosure can be effectively attached to a curved surface, physical damage to nearby tissues can be reduced. Also, it can be implanted into a small space since the substrate thickness is small and the light weight prevents damage to the body. In addition, effective photodynamic therapy is possible with low power and the kind, intensity, etc. of light can be controlled precisely.

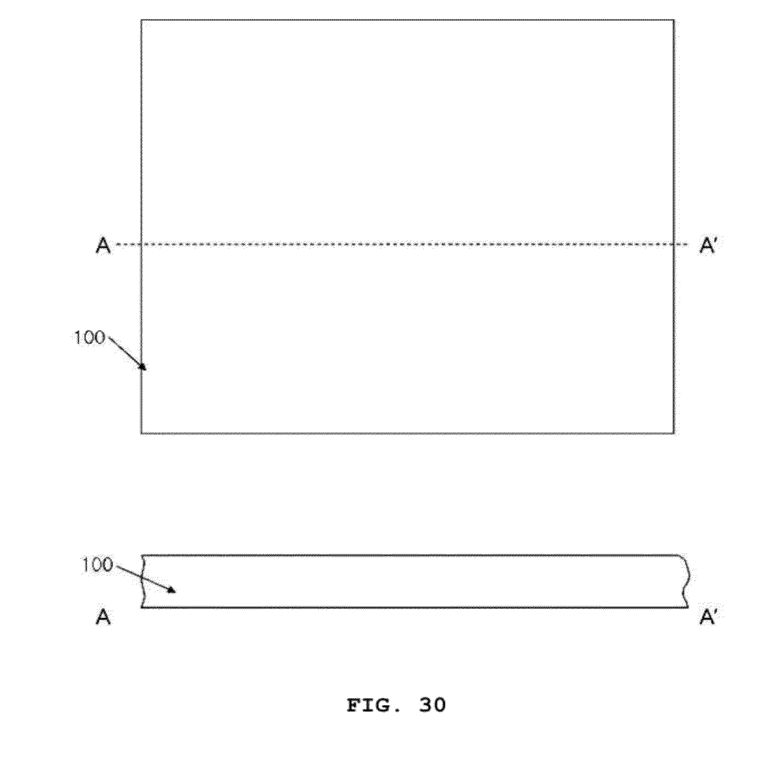

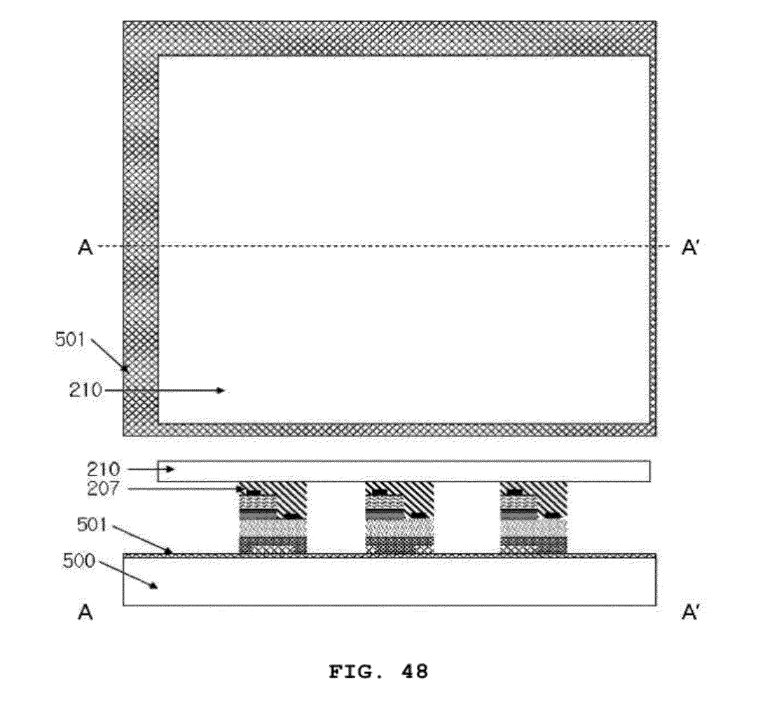

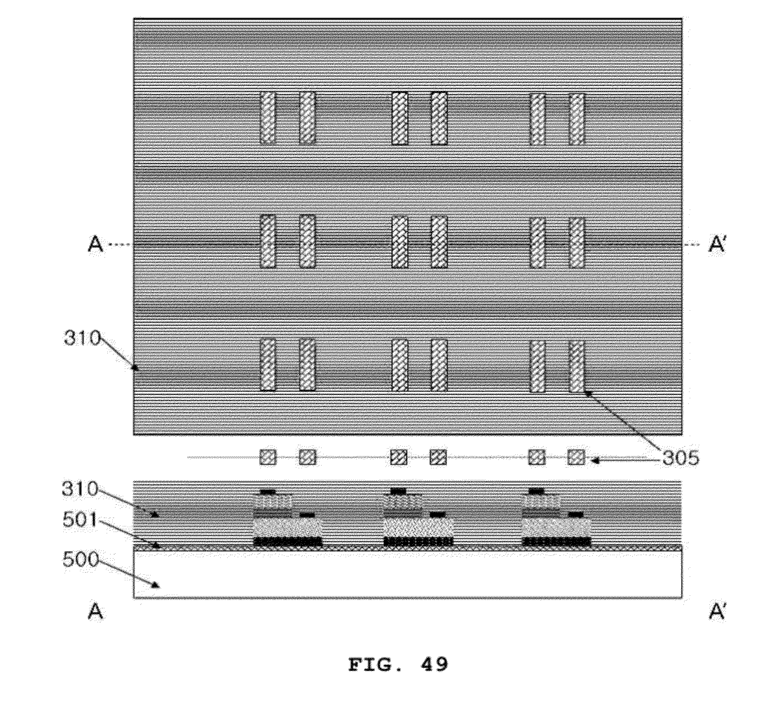

FIGS. 30-59 illustrate a method for fabricating a flexible GaN LED device according to an exemplary embodiment of the present disclosure.

FIG. 30 shows a sapphire substrate (100) as sacrificial substrate.

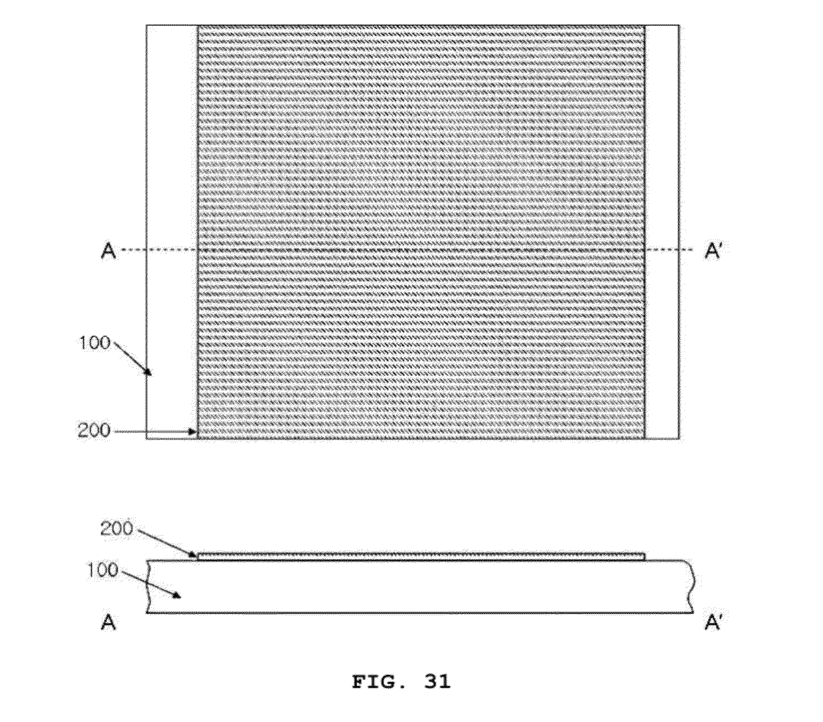

Referring to FIG. 31, a silicon oxide layer (200) is formed on the sapphire substrate (100).

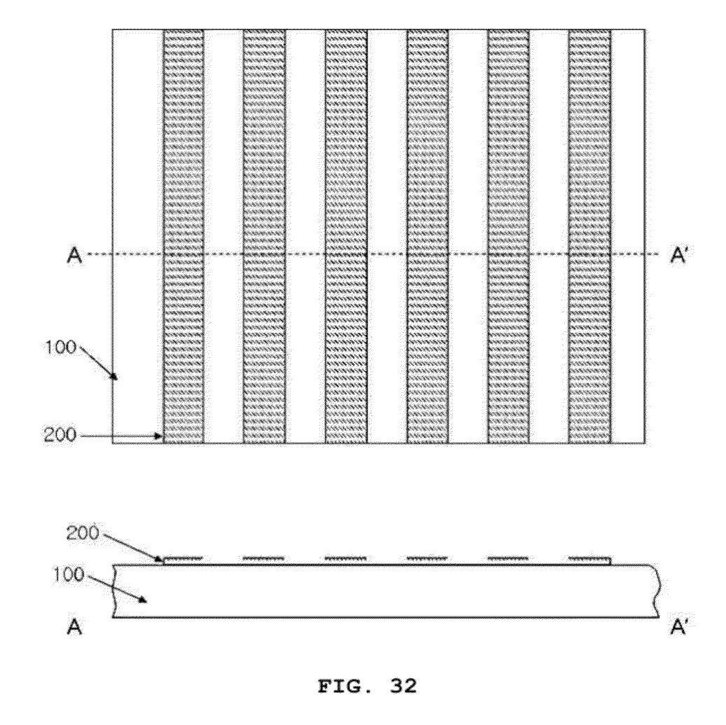

Referring to FIG. 32, a photoresist layer is formed on the silicon oxide layer (200) and patterning is performed after a mask layer is formed on the photoresist layer. the exposed silicon oxide layer (200) is removed by a photolithography process and an etching process, and the photoresist layer remaining on the silicon oxide layer (200) is removed. As a result, the silicon oxide layer (200) is obtained as a plurality of columns spaced from each other.

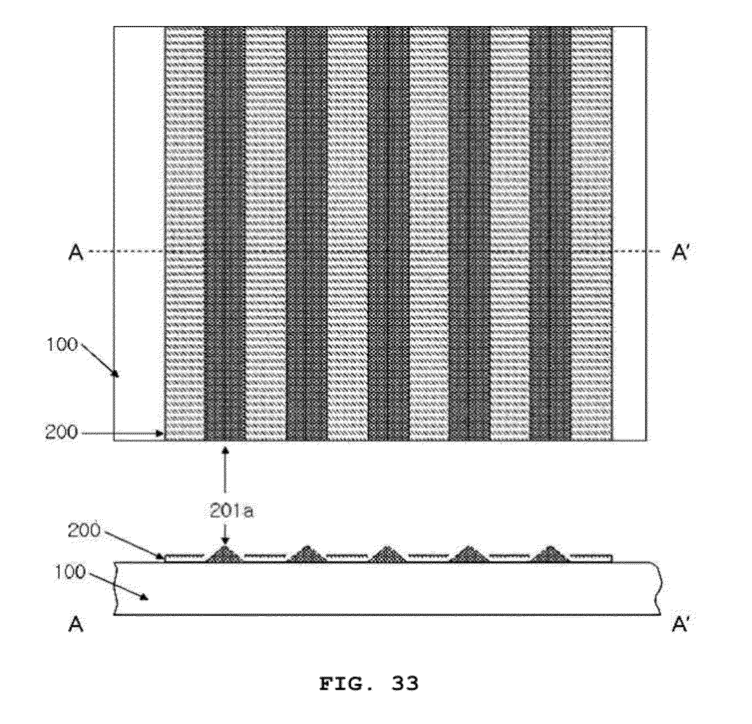

Referring to FIG. 33, a first GaN layer (201a) is grown on the sapphire substrate (100) exposed between the plurality of columns of the silicon oxide layer (200). The first GaN layer (201a) is grown by an epitaxial lateral overgrowth method. In this method, GaN crystals grow laterally. As a result, the first GaN layer (201a) grows between the oxide layer (200) in triangular shape as shown in FIG.

35.

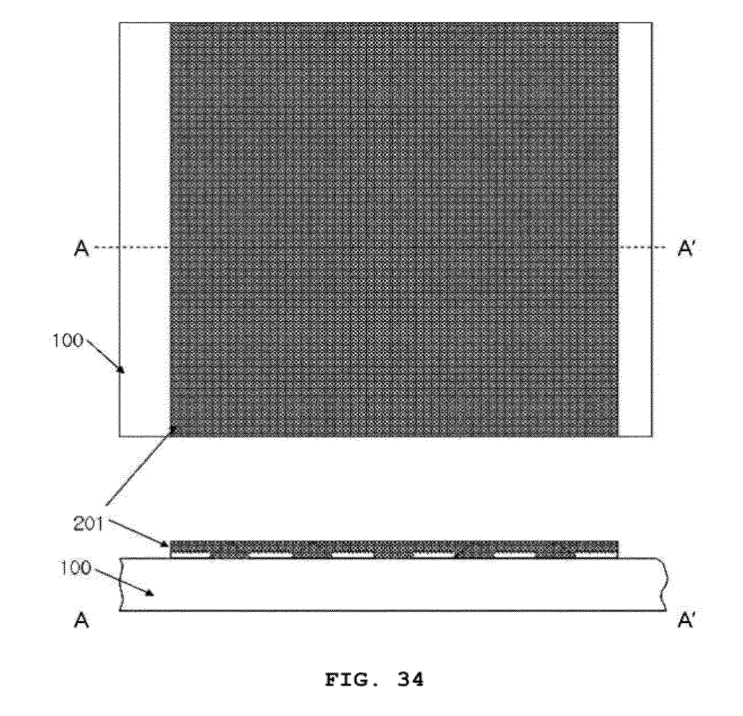

Referring to FIG. 34, a second GaN layer (201) is formed on the laterally overgrown first GaN layer (201a).

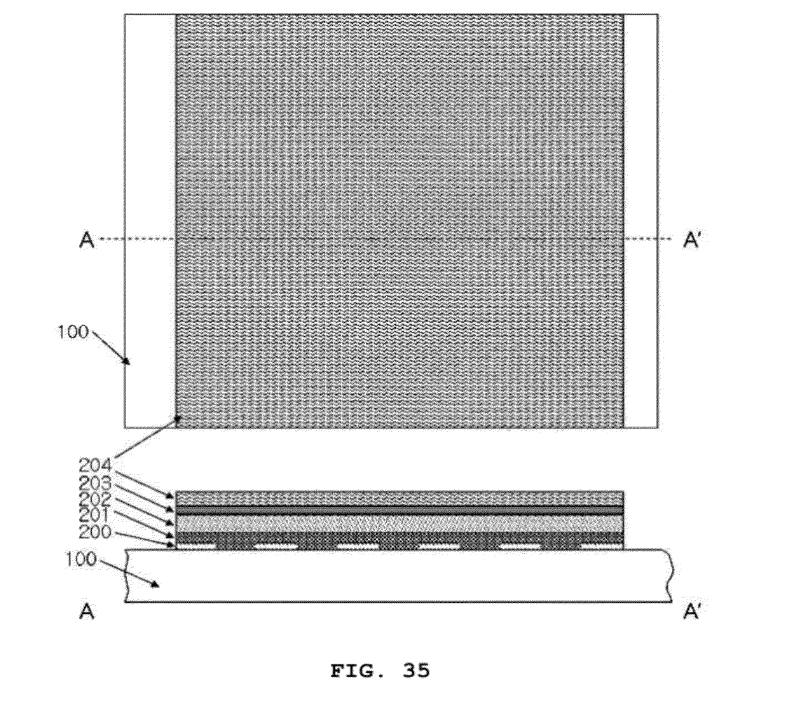

Referring to FIG. 35, an n-type impurity-doped n-GaN layer (202), a light-emitting multi-quantum well layer (203) and a p-type impurity-doped p-GaN layer (204) are formed sequentially on the GaN layer (201).

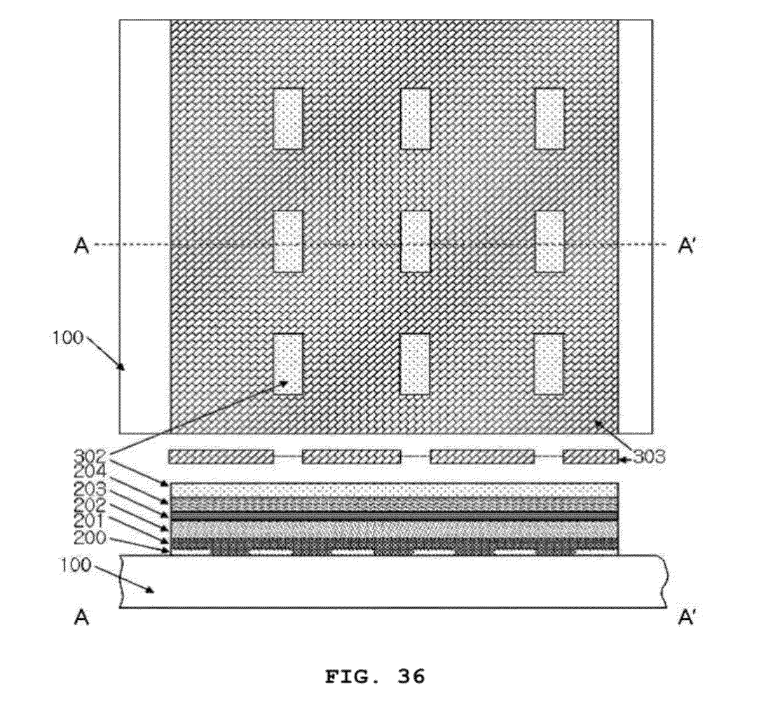

Referring to FIG. 36, after a photoresist layer (302) and a mask layer (303) are formed sequentially on the p-GaN layer (204), the mask layer (303) is patterned.

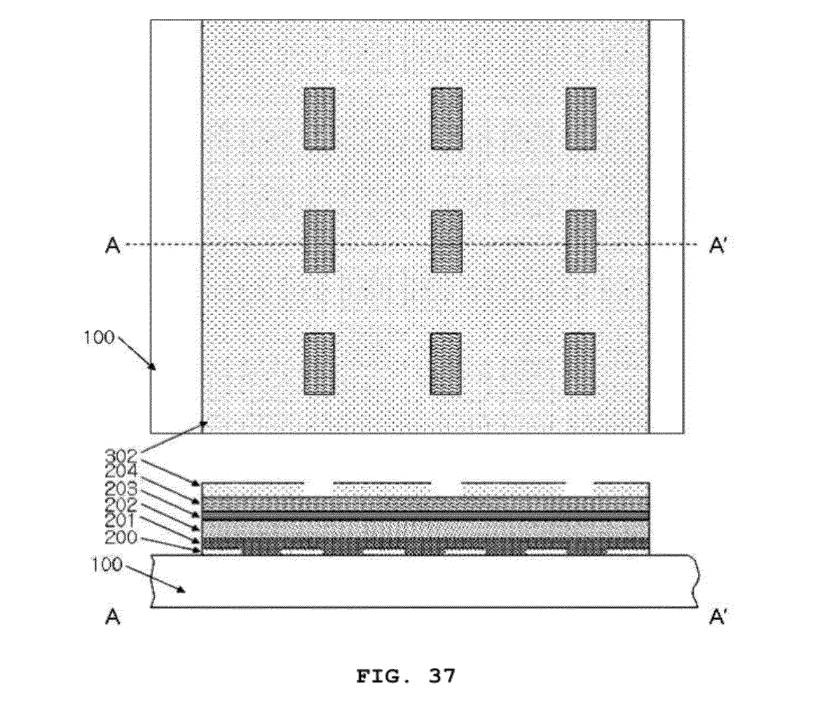

Referring to FIG. 37, the photoresist layer (302) exposed between the mask layer (303) is etched to expose the p-GaN layer (204).

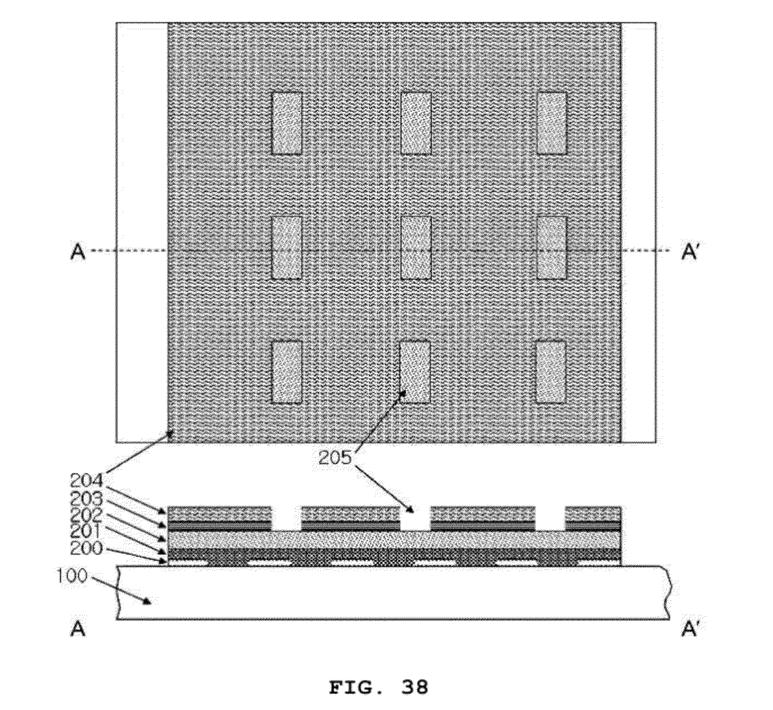

Referring to FIG. 38, the light-emitting layer (203) below the exposed p-GaN layer (204) is etched by a reactive-ion etching (RIE) process so as to define an n-GaN region (205), i.e. the region where the n-GaN layer (202) is exposed to outside.

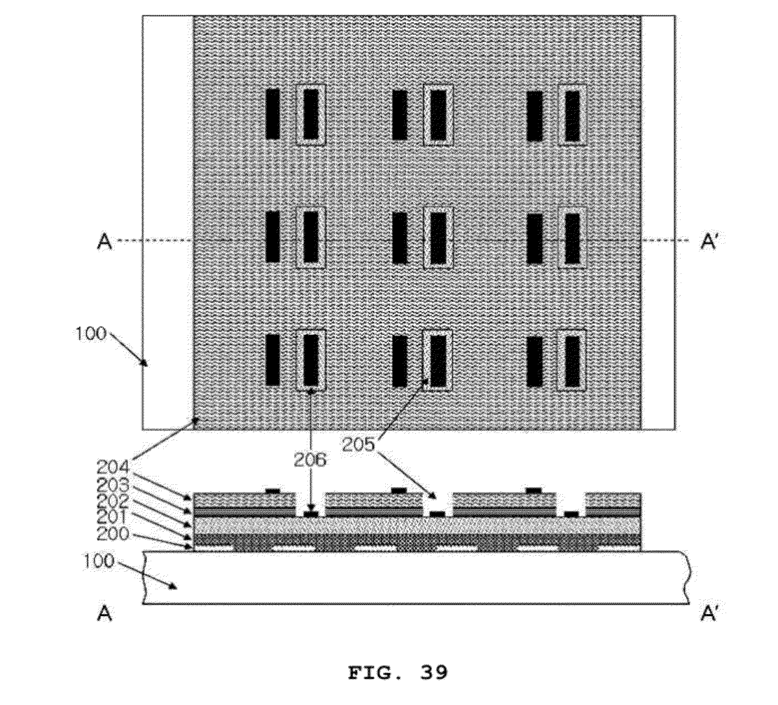

Referring to FIG. 39, a metal contact (206) is formed on the n-GaN region (205) and the p-GaN layer (204), respectively. In an exemplary embodiment of the present disclosure, the metal contact (206) comprises Au/Cr alloy. After the metal contact (206) is formed, an ohmic contact is formed with a device layer by a rapid thermal annealing (RTA) process at 600° C. for 1 minute.

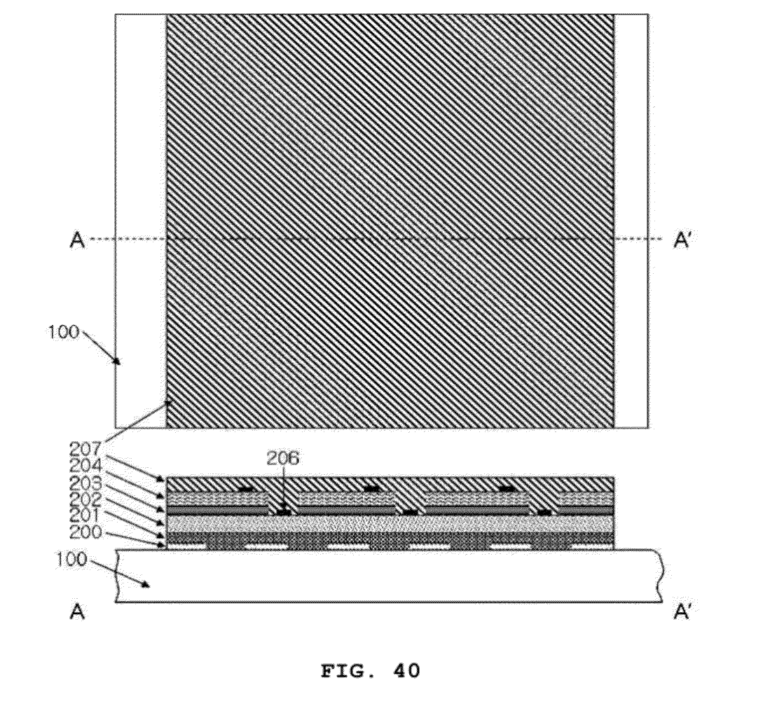

Referring to FIG. 40, a second metal layer (207) for supporting the GaN layer is formed on the front side of the substrate of FIG. 12. The second metal layer may also comprise Au/Cr alloy as the metal contact. However, the scope of the present disclosure is not limited thereto.

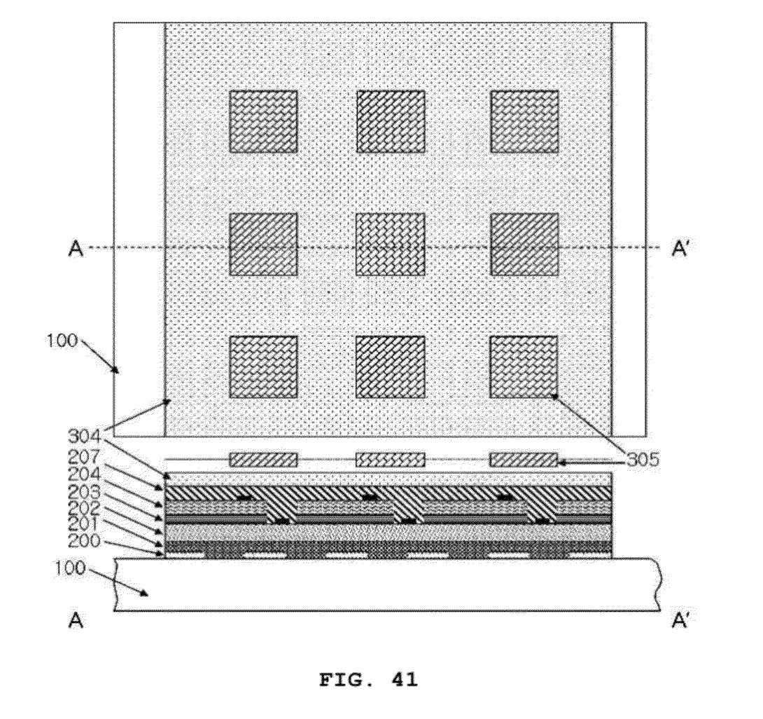

Referring to FIG. 41, a photoresist layer (304) is formed on the second metal layer (207), and then a patterned mask layer (305) is formed. The mask layer (305) covers the whole region where the metal contact is formed. As a result, a GaN LED device having the same shape and size as the mask layer (305) is fabricated.

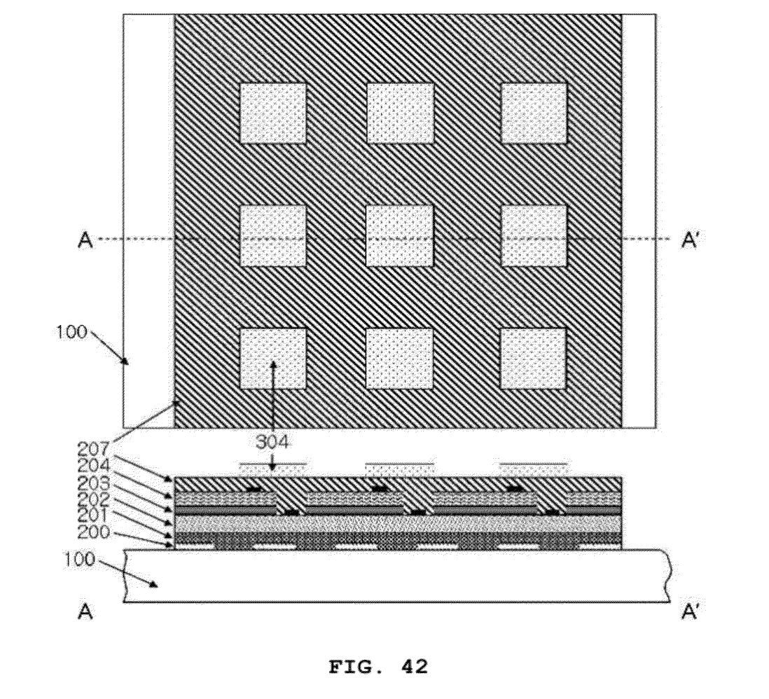

Referring to FIG. 42, the photoresist layer (304) is removed by a photolithography process excluding the region where the mask layer (305) is formed.

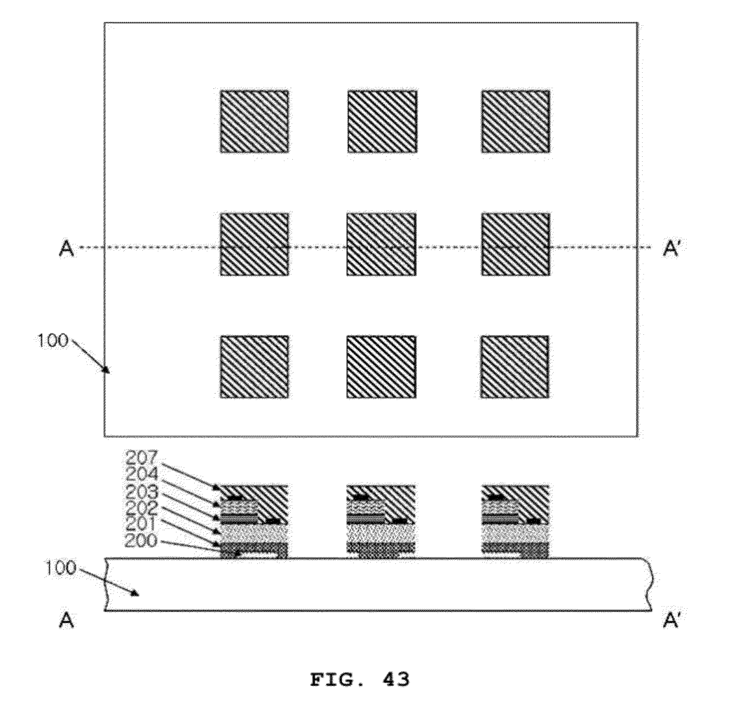

Referring to FIG. 43, the device layer is removed completely by an RIE process except for the device layer below the remaining photoresist layer (304). As a result, a plurality of GaN LED unit devices are formed on the sapphire substrate (100).

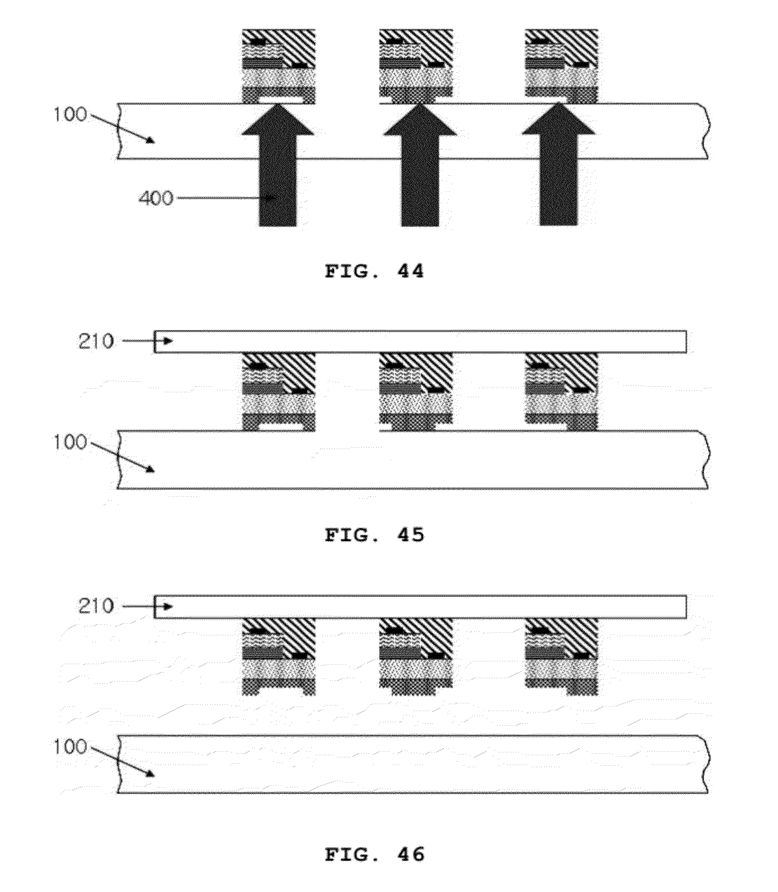

Referring to FIG. 44, the silicon oxide layer (200) remaining on the sapphire substrate (100) is removed using HF. That is to say, the GaN LED unit device is removed from the sacrificial substrate by a chemical lift-off method. For this, a sacrificial layer (In an exemplary embodiment of the present disclosure, the sacrificial layer is a silicon oxide layer.) reacting with a specific chemical substance is provided between the substrate and the device. By this chemical lift-off process, the adhesivity between the sapphire substrate (100) and the GaN unit device becomes weak, and the GaN unit device can be effectively separated from the sacrificial substrate by a transfer substrate (210).

Referring to FIG. 45, the GaN unit device with the silicon oxide layer (200) removed, more specifically the second metal layer (207) of the device is contacted with a transfer substrate (210) comprising, e.g., PDMS.

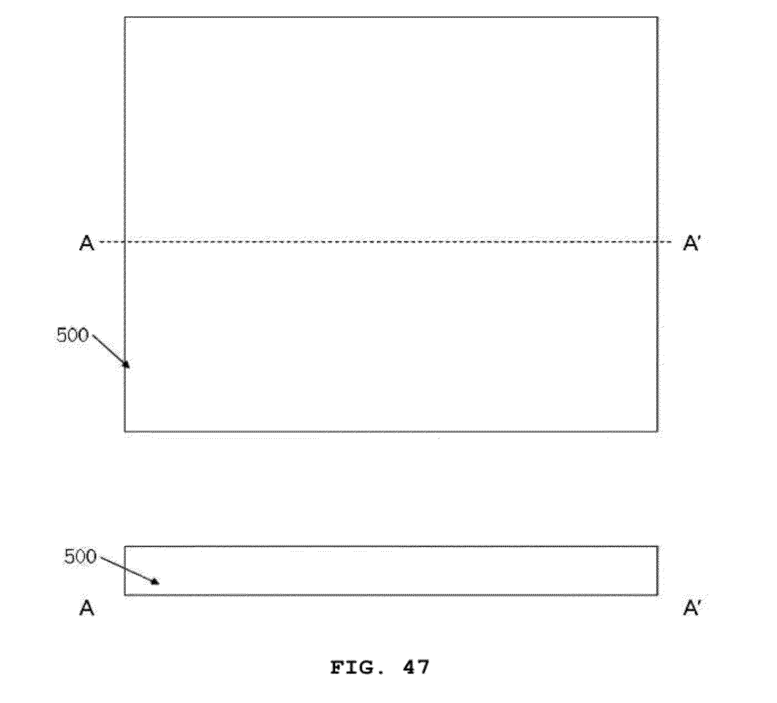

Referring to FIG. 46, the GaN LED unit device is separated from the sapphire substrate (100) which is a sacrificial substrate by the transfer substrate (210). Referring to FIGS. 47-49, the GaN LED device separated from the sapphire substrate (100) in FIG. 46 is transferred to a plastic substrate (500) on which an adhesive layer (501) is formed using the transfer substrate (210), and then the PDMS transfer substrate (210) is removed.

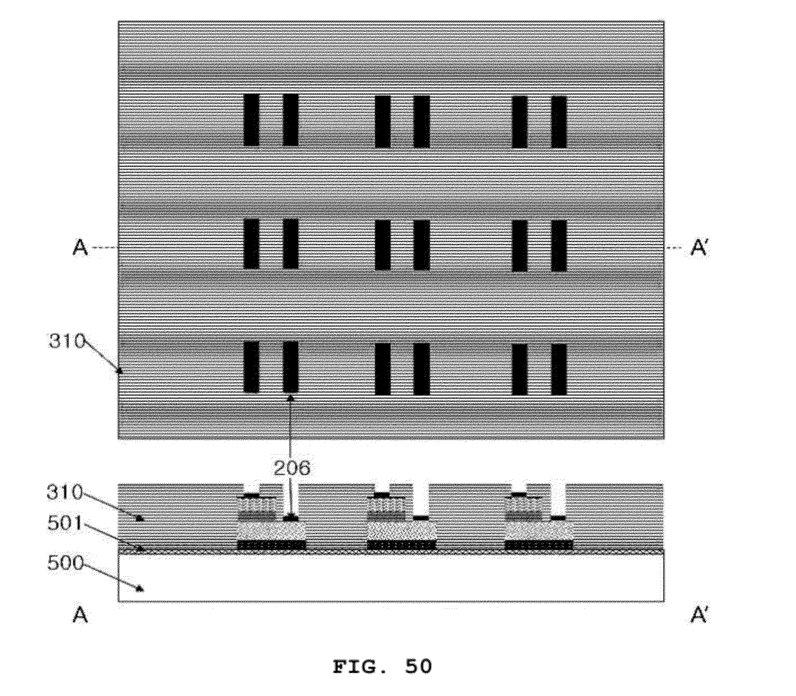

Referring to FIG. 50 the second metal layer (207) is removed to provide a sufficient contact area with the PDMS transfer substrate.

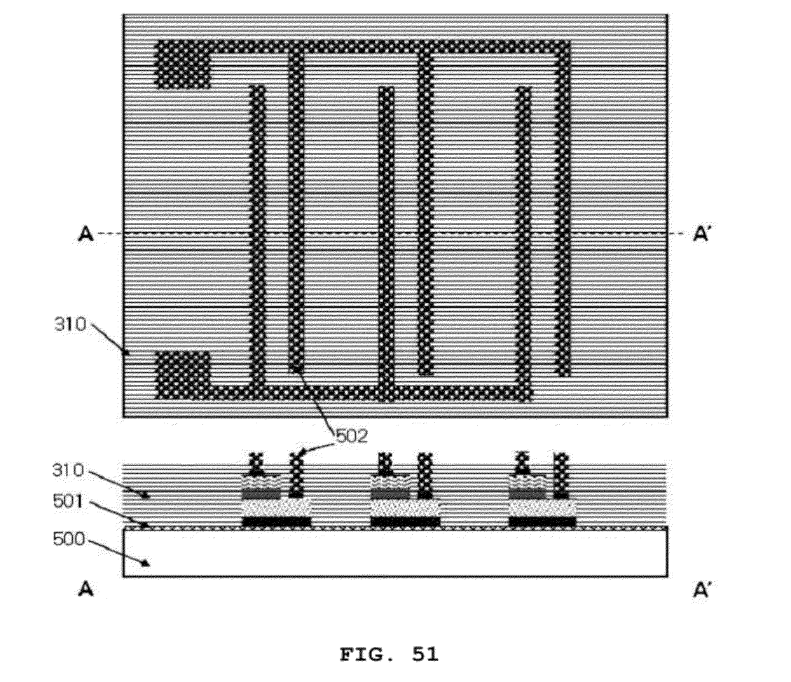

Referring to FIG. 51 a first transparent insulating layer (epoxy, 310) for electrical passivation of the device is coated on the plastic substrate (500) and a mask layer (306) for exposing a first metal layer of the device to outside is formed. In an exemplary embodiment of the present disclosure, the first transparent insulating layer (310) may comprise a polymer material such as SU8, polyimide, polyurethane, etc. However, the scope of the present disclosure is not limited thereto.

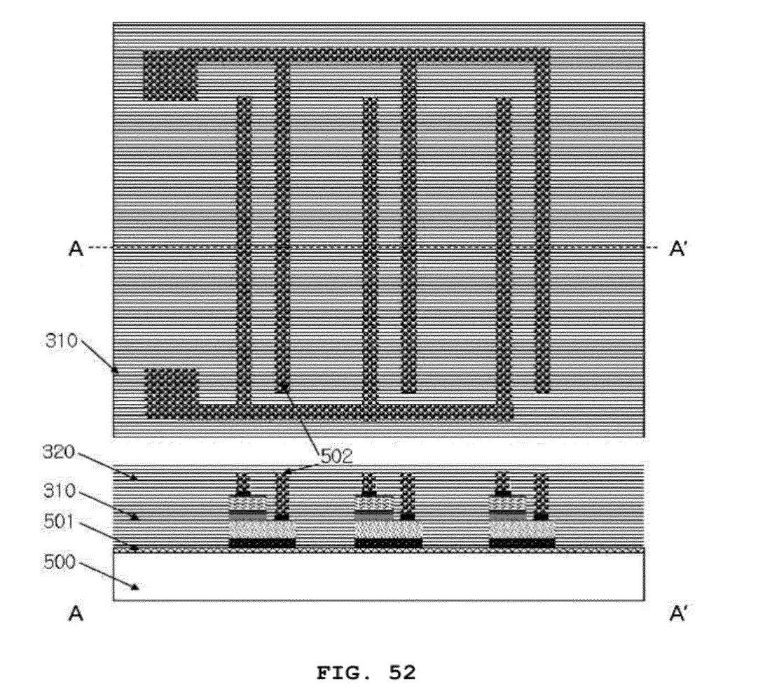

Referring to FIG. 52 the first transparent insulating layer (310) is partially removed by a photolithography process using the mask layer (306) so as to expose the first metal layer (206) formed respectively on the p-GaN layer and the n-GaN layer to outside.

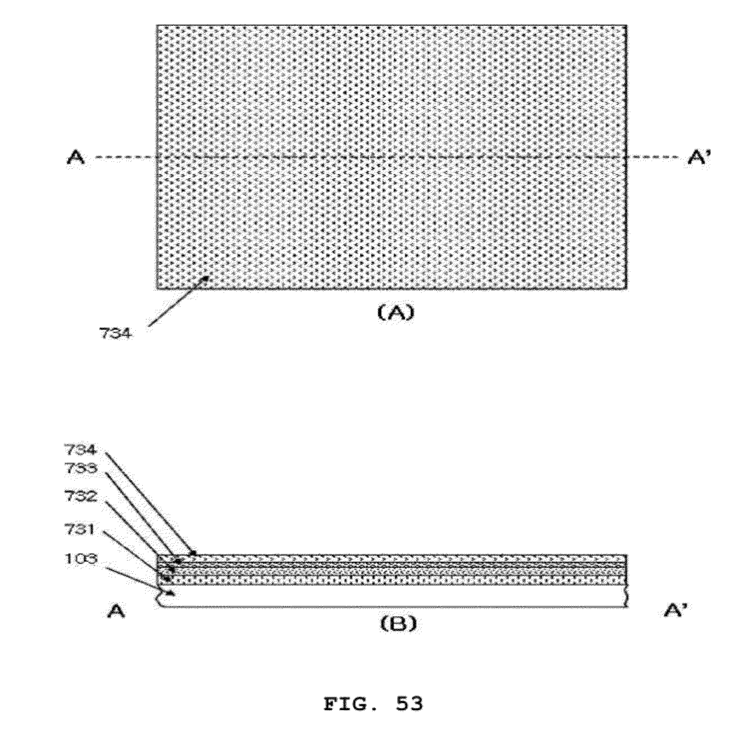

Referring to FIG. 53 a first metal line (502) is formed on the metal contact (n-GaN metal contact) (206) formed on the n-GaN layer at lower height. In an exemplary embodiment of the present disclosure, the first metal line (502) is formed to electrically connect one or more GaN LED unit devices to the n-GaN metal contact.

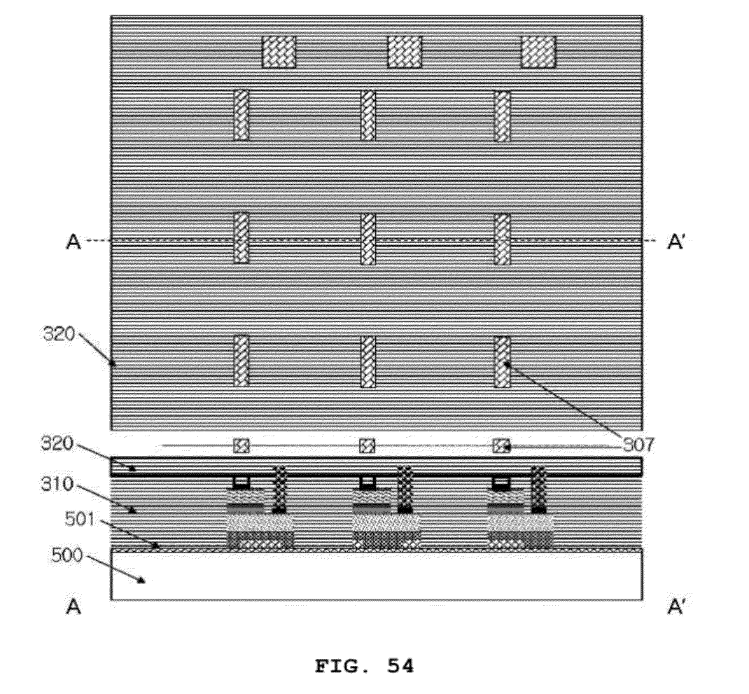

Referring to FIG. 54 a second transparent insulating layer (320) is formed on the substrate and a mask layer (307) for connection with the ohmic contact of the p-GaN layer is formed on the second transparent insulating layer (320).

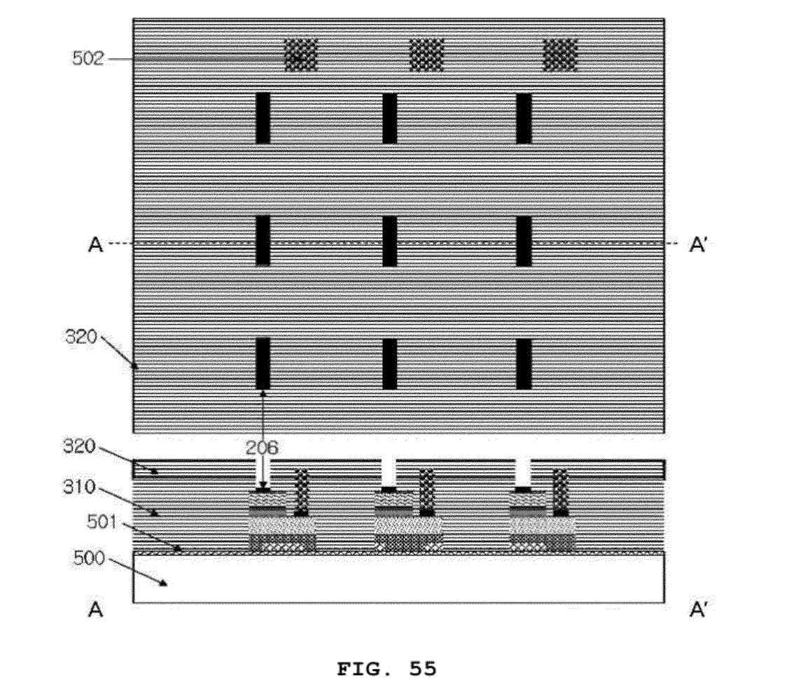

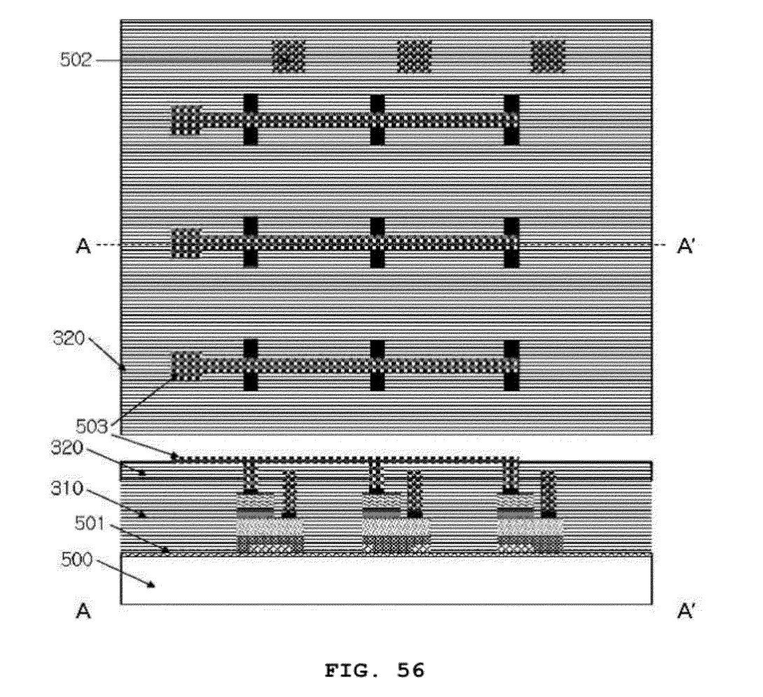

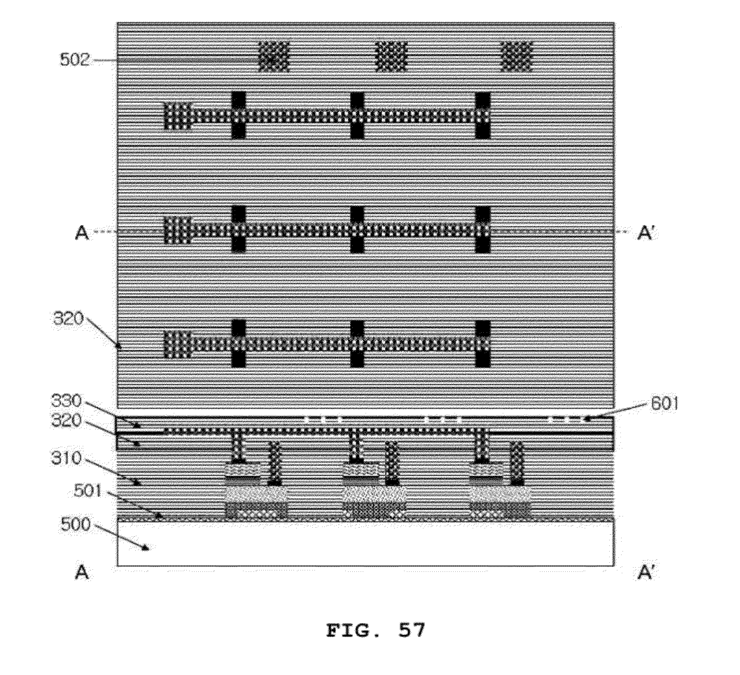

Referring to FIGS. 55 and 56 the metal contact (206) formed on the p-GaN layer at higher height is exposed by a photolithography process using the mask layer (307), and then a second metal line (503) electrically connecting the metal contact (206) is formed. The end portion of the first metal line (502) formed at lower height is exposed between the second transparent insulating layer. In an exemplary embodiment of the present disclosure, the first metal line and the second metal line are formed at different heights and connect the unit device in different directions. That is to say, if the first metal line connecting the n-GaN layer provides connection in the vertical direction, the second metal line provides connection in the horizontal direction. Thus, an array-type flexible light source having the plurality of GaN LED unit devices arranged as rows and columns is embodied.

The present disclosure also provides an optical device for optogenetics using the plurality of flexible GaN LED unit devices, which will be described in detail hereunder.

FIGS. 57-59 illustrate a method for fabricating an optical device for optogenetics according to an exemplary embodiment of the present disclosure.

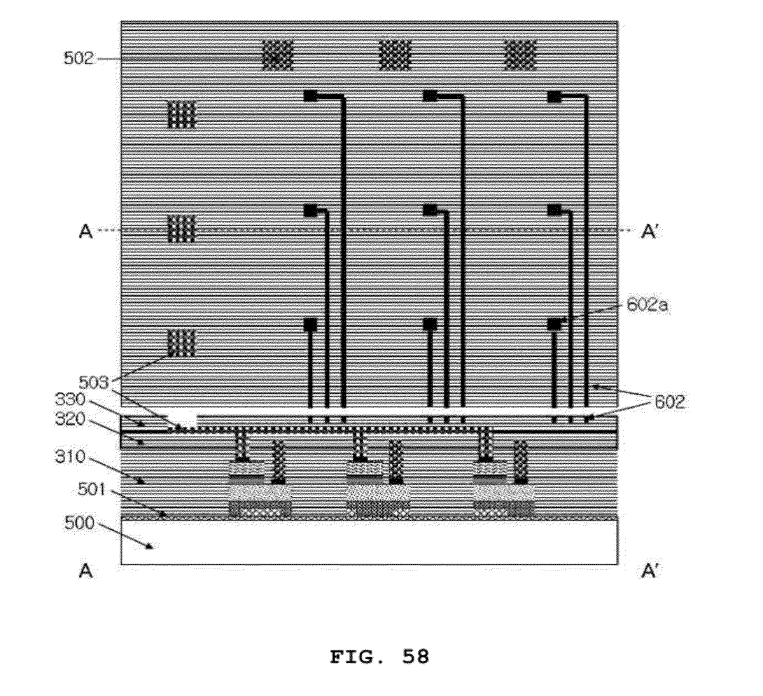

Referring to FIG. 57, a third transparent insulating layer (330) is formed on the second transparent insulating layer (320) of the plurality of GaN LED unit devices shown in FIG. 58, and then a micropattern (601) for forming a microelectrode array (MEA) is formed on the third transparent insulating layer (320). The third transparent insulating layer (330) is patterned, so that an end portion (first metal line pad, 502) connected to the first metal line and an end portion (second metal line pad, 503) connected to the second metal line are exposed to outside.

Referring to FIG. 58, the third transparent insulating layer (330) is etched to a predetermined depth, such that the microelectrode array pattern (601) is patterned to and an MEA electrode line (602) is form. An electrode pad (602a) narrower than the MEA electrode line is connected at an end portion thereof.

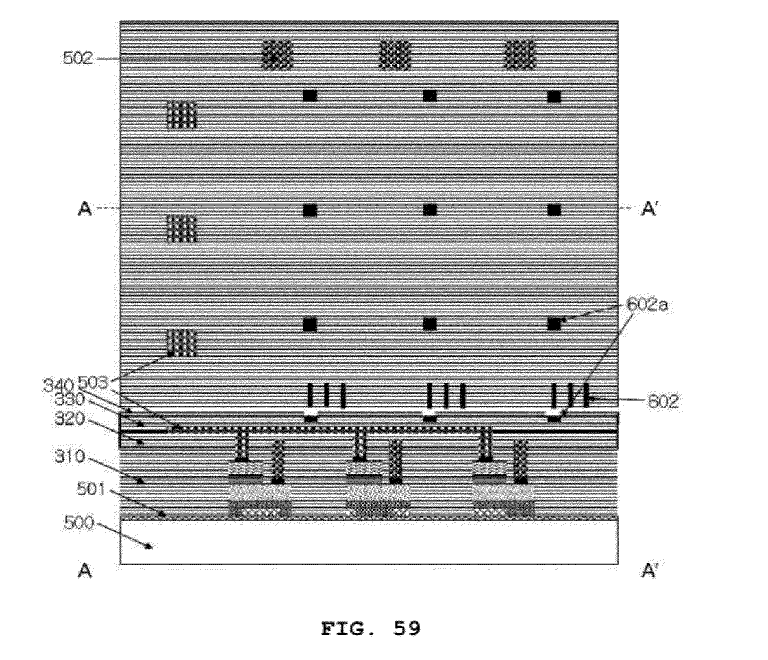

Referring to FIG. 59, a fourth transparent insulating layer (340) which is the final insulating layer is formed on the third transparent insulating layer (330). Then, the fourth transparent insulating layer (340) is patterned such that the end portions of the first and second metal lines (502, 503) connected to the MEA electrode line, t he pad and the GaN LED line are exposed. As a result, an array-type electrode is formed for each unit GaN LED device based on the first and second metal lines, and a microelectrode array for electrically detecting the change in neurons in response to the light emitted independently from each unit GaN LED device is formed.

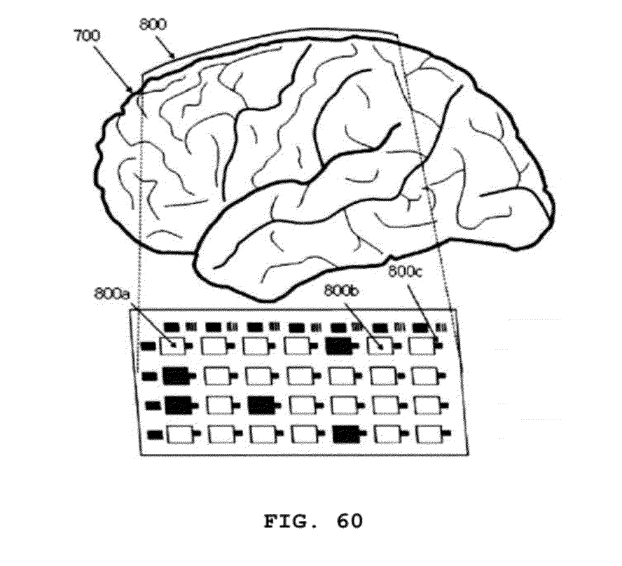

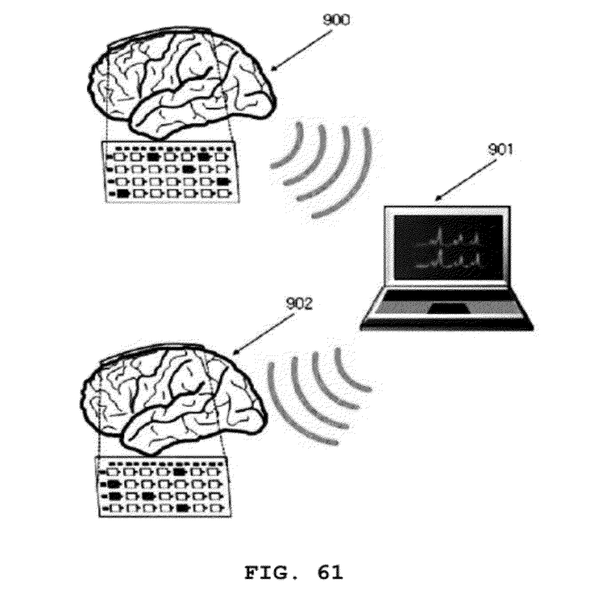

FIG. 60 schematically illustrates a method for providing a patterned stimulation using a flexible LED array (800a, 800b) according to an exemplary embodiment of the present disclosure and reading the response using an MEA (800c).

Referring to FIG. 60, some of the unit GaN LED devices (800b) are turned on while other (800c) are turned off. The MEA configured to match 1:1 with each of the unit devices electrically measures the change in neurons in response to the light emitted from each unit device.

FIG. 61 illustrates an exemplary use of an optical device for optogenetics according to an exemplary embodiment of the present disclosure.

Referring to FIG. 61, a GaN LED optical device for optogenetics according to the present disclosure as shown above is turned on/off and the change in action potential of neurons in response thereto is measured (900). Then, the measured change is transmitted to outside (901). Subsequently, the unit devices of the optical GaN LED device for optogenetics implanted in the body are turned on/off according to an input signal from outside.

The flexible GaN LED device fabricated according to the present disclosure can emit light as attached onto curved surface in the body. Therefore, it can be easily stimulate the uneven surface of the round skull or the cerebral cortex (associated with recognition, thinking, language, memory etc.; in particular, Parkinson's disease is associated with damage to the neurons on the surface of the cerebral cortex) just below the skull and can be implanted in the deep narrow crevice between the left and right cerebral hemispheres. Since a plurality of LEDs that can be turned on/off independently are arranged as an array, neurons of several areas can be stimulated with light and thus it becomes easier to understand the neural circuitry. In addition, since the MEA electrode line of the flexible optical device for optogenetics according to the present disclosure is partially exposed, the action potential of neurons in response to the light emitted from the GaN LED device can be detected by the MEA electrode and then fed back.

The GaN LED array device for optogenetics according to the present disclosure is very useful in that it has light weight, is implantable and can be used in a small space through size control. For example, the spinal neurons branching through the bones of the spine may be easily damaged in case of disc herniation, external injury, spinal curvature, or the like. The damage to the spinal neurons is associated with various physical symptoms (problems with digestive organs, heart, blood vessels, bladder, sweat glands, etc.). However, since the spine is not straight but curved, it is impossible to use a hard LED. In contrast, the flexible LED device according to the present disclosure may be implanted for use under such environments. In particular, the optogenetic system according to the present disclosure that can be self-powered in vivo is very useful for the patients who cannot move freely.

While the present disclosure has been described with respect to the specific embodiments, it will be apparent to those skilled in the art that various changes and modifications may be made without departing from the spirit and scope of the disclosure as defined in the following claims

1. A method for fabricating a flexible light-emitting diode (LED) device, comprising:
separating an LED device fabricated on a sacrificial substrate from the sacrificial substrate; and
transferring the separated LED device to a plastic substrate.

2. The method for fabricating an LED device of claim 1, wherein said separating the LED device from the sacrificial substrate is performed by a laser beam lift-off method of irradiating a laser beam on the rear surface of the sacrificial substrate.

3. The method for fabricating an LED device of claim 1, wherein said separating the LED device from the sacrificial substrate is performed by etching a sacrificial layer formed on the sacrificial substrate with a chemical solution.

4. The method for fabricating an LED device of claim 1, wherein the LED device is a GaN or GaAs device.

5. The method for fabricating an LED device of claim 4, wherein the LED device is an LED device for optogenetics, skin therapy or photodynamic therapy.

6. A method for fabricating a flexible GaN LED array device, comprising:
forming a GaN LED array comprising a plurality of GaN LED unit devices spaced apart from each other on a sacrificial substrate;
separating the GaN LED array from the sacrificial substrate and transferring to a plastic substrate;
forming a contact line connected to the transferred GaN LED unit devices; and
forming a passivation layer on the contact line and partly exposing the contact line to outside.

7. The method for fabricating a flexible GaN LED array device of claim 6, wherein the GaN LED unit device comprises an n-GaN layer, a multi-quantum well (MQW) layer as an active layer and a p-GaN layer.

8. The method for fabricating a flexible GaN LED array device of claim 6, wherein contact metals are formed on the n-GaN layer and the p-GaN with different heights.

9. A method for fabricating a flexible GaN LED device, comprising:
fabricating a GaN LED device on a sacrificial substrate; and
chemically separating the GaN LED device from the sacrificial substrate,
wherein the chemical separation comprises chemically removing a sacrificial layer between the sacrificial substrate and the GaN LED device.

10. The method for fabricating a flexible GaN LED device of claim 9, which comprises:
forming a silicon oxide layer on a sacrificial substrate;
patterning the silicon oxide layer to form an array of a plurality of silicon oxide layers spaced apart from each other;
growing a first GaN layer in the space between the silicon oxide layers;
forming a second GaN layer on the silicon oxide layer and the first GaN layer;
forming a GaN device layer comprising sequentially an n-GaN layer, a light-emitting layer and a p-GaN layer on the second GaN layer;
patterning the GaN device layer to form a plurality of unit GaN LED devices; and
removing the silicon oxide layer from the sacrificial substrate and transferring the plurality of unit GaN LED devices to a plastic substrate.

11. The method for fabricating a flexible GaN LED device of claim 10, wherein the removal of the silicon oxide layer is performed by a chemical method.

12. The method for fabricating a flexible GaN LED device of claim 9, wherein the GaN LED device comprises an array of a plurality of unit LED devices.

13. The method for fabricating a flexible GaN LED device of claim 12, which further comprises, after the formation of the GaN device layer:
exposing the n-GaN layer and the p-GaN layer to outside;
forming metal contacts respectively on the n-GaN layer and the p-GaN layer; and
forming a first metal line connecting the metal contact on the n-GaN layer and a second metal line connecting the metal contact on the p-GaN layer.

14. The method for fabricating a flexible GaN LED device of claim 13, wherein the growth of the first GaN layer is performed by an epitaxial lateral overgrowth method.
